(19) United States
(12) Patent Application Publication
(10) Pub. No.: US 2026/0104302 A1
(43) Pub. Date: Apr. 16, 2026

(54) STRETCHABLE PANEL AND ELECTRONIC DEVICE

(71) Applicant: Samsung Electronics Co., Ltd., Suwon-si (KR)

(72) Inventors: Gae Hwang LEE, Suwon-si (KR); Hyun Bum KANG, Suwon-si (KR); Yasutaka KUZUMOTO, Suwon-si (KR); Hyung Jun KIM, Suwon-si (KR)

(73) Assignee: Samsung Electronics Co., Ltd., Suwon-si (KR)

(21) Appl. No.: 19/181,916

(22) Filed: Apr. 17, 2025

(30) Foreign Application Priority Data
May 14, 2024 (KR) 10-2024-0063390
Apr. 10, 2025 (KR) 10-2025-0047071

(51) Int. Cl. G01L 1/22; H10H 29/49; H10H 29/85; H10K 59/131; H10K 77/10

(52) U.S. Cl. CPC G01L 1/2293; G01L 1/2243; H10H 29/49; H10H 29/8508; H10K 59/131; H10K 77/111

(57) ABSTRACT

A stretchable panel includes a stretchable substrate, and a strain sensor on the stretchable substrate, wherein the strain sensor includes a first gate electrode, a first polymer semiconductor layer overlapped with the first gate electrode along a thickness direction of the stretchable substrate and including polymer chains of the first polymer semiconductor layer, and a first source electrode and a first drain electrode electrically connected to the first polymer semiconductor layer and facing each other with the first polymer semiconductor layer interposed therebetween, and the polymer chains of the first polymer semiconductor layer are oriented so as to cross a first channel length direction extending from the first source electrode to the first drain electrode.

### CROSS-REFERENCE TO RELATED APPLICATIONS

This application claims priority to and the benefit of Korean Patent Application No. 10-2024-0063390 filed in the Korean Intellectual Property Office on May 14, 2024, and Korean Patent Application No. 10-2025-0047071 filed in the Korean Intellectual Property Office on Apr. 10, 2025, the entire contents of each of which are incorporated herein by reference.

### BACKGROUND

### 1. Field

A stretchable panel and an electronic device are related.

### 2. Description of the Related Art

In recent years, research on a stretchable panel such as a display panel that can be curved, bent, or folded or a wearable sensor array that are attached to a living body or an object is in progress. Such a stretchable panel may have stretchability such that the stretchable panel may be stretched or restored according to motions of the living body or shapes of the object. Such a stretchable panel may have flexibility such that the stretchable panel may be curved, bent, or folded in a particular (or, alternatively, predetermined) direction.

### SUMMARY

Some example embodiments provide a stretchable panel that may reduce, minimize, or prevent performance degradation due to stretching, including for example differences in performance, such as display quality that may occur between an area where the strain is applied and an area where the strain is not applied according to local strain due to the stretching. Accordingly, the display performance of the stretchable panel, and any device including same, may be improved based on reducing, minimizing, or preventing occurrence of display performance degradation due to stretching of one or more portions of the stretchable panel.

Some example embodiments provide an electronic device including the stretchable panel.

According to some example embodiments, a stretchable panel may include a stretchable substrate, and a strain sensor on the stretchable substrate. The strain sensor may include a first gate electrode, a first polymer semiconductor layer overlapped with the first gate electrode along a thickness direction of the stretchable substrate and including polymer chains of the first polymer semiconductor layer, and a first source electrode and a first drain electrode electrically connected to the first polymer semiconductor layer and facing each other with the first polymer semiconductor layer interposed therebetween. The polymer chains of the first polymer semiconductor layer may be oriented so as to cross a first channel length direction extending from the first source electrode to the first drain electrode.

The polymer chains of the first polymer semiconductor layer may be oriented at an angle of 45 degrees to 135 degrees with respect to the first channel length direction.

The polymer chains of the first polymer semiconductor layer may be oriented perpendicularly to the first channel length direction.

The first polymer semiconductor layer may include a plurality of semiconductor stripes extending perpendicularly to the first channel length direction, and each semiconductor stripe of the plurality of semiconductor stripes may comprise at least a portion of the polymer chains of the first polymer semiconductor layer.

The stretchable panel may further include a non-stretchable pattern on the stretchable substrate and having a higher elastic modulus than the stretchable substrate, and the stretchable panel may include a non-stretchable region in which the stretchable substrate and the non-stretchable pattern are arranged to be overlapped each other, and a stretchable region excluding the non-stretchable region, and the strain sensor may be in the stretchable region.

The strain sensor may include first and second strain sensors which are arranged separately from each other in the stretchable region, and the first channel length direction of the second strain sensor may be different from the first channel length direction of the first strain sensor.

The stretchable panel may further include a plurality of unit elements and a plurality of pixel circuits electrically connected to the plurality of unit elements, the plurality of unit elements may include a light emitting diode, a photoelectric conversion diode, or any combination thereof, and the plurality of unit element may be in the non-stretchable region.

At least a portion of at least one pixel circuit of the plurality of pixel circuits may be in the non-stretchable region.

A portion of at least one pixel circuit of the plurality of pixel circuits may be in the non-stretchable region and a separate portion of the at least one pixel circuit may be in the stretchable region.

At least one pixel circuit of the plurality of pixel circuits may include a thin film transistor, the thin film transistor may include a second gate electrode, a second polymer semiconductor layer overlapped with the second gate electrode along a thickness direction of the stretchable substrate and including polymer chains of the second polymer semiconductor layer, and a second source electrode and a second drain electrode electrically connected to the second polymer semiconductor layer and facing each other with the second polymer semiconductor layer interposed therebetween, and the polymer chains of the second polymer semiconductor layer may be oriented parallel to a second channel length direction extending from the second source electrode to the second drain electrode.

The first polymer semiconductor layer and the second polymer semiconductor layer may include a same polymer.

According to some example embodiments, a stretchable panel may include a stretchable substrate, and a first thin film transistor and a second thin film transistor are arranged on the stretchable substrate, wherein the first thin film transistor includes a first gate electrode, a first polymer semiconductor layer overlapped with the first gate electrode along a thickness direction of the stretchable substrate and including polymer chains of the first polymer semiconductor layer, and a first source electrode and a first drain electrode electrically connected to the first polymer semiconductor layer and facing each other with the first polymer semiconductor layer interposed therebetween, the second thin film transistor includes a second gate electrode, a second polymer semiconductor layer overlapped with the second gate electrode along the thickness direction of the stretchable substrate and layer including polymer chains of the second polymer semiconductor layer, and a second source electrode and a second drain electrode electrically connected to the second polymer semiconductor layer and facing each other with the second polymer semiconductor layer interposed therebetween. The polymer chains of the first polymer semiconductor layer may be oriented so as to cross a first channel length direction extending from the first source electrode to the first drain electrode, and the polymer chains of the second polymer semiconductor layer may be parallel to a second channel length direction extending from the second source electrode to the second drain electrode.

The polymer chains of the first polymer semiconductor layer may be oriented at an angle of 45 degrees to 135 degrees with respect to the first channel length direction.

The polymer chains of the first polymer semiconductor layer may be oriented perpendicularly to the first channel length direction.

The stretchable panel may further include a non-stretchable pattern on the stretchable substrate and having a higher elastic modulus than the stretchable substrate, the stretchable panel may include a non-stretchable region in which the stretchable substrate and the non-stretchable pattern are arranged to be overlapped each other, and a stretchable region excluding the non-stretchable region, the first thin film transistor may be arranged in the stretchable region, and the second thin film transistor may be arranged in the non-stretchable region.

The stretchable panel may further include a third thin film transistor electrically connected to the second thin film transistor, the third thin film transistor may include a third gate electrode, a third polymer semiconductor layer overlapped with the third gate electrode along the thickness direction of the stretchable substrate and including polymer chains of the third polymer semiconductor layer, and a third source electrode and a third drain electrode electrically connected to the third polymer semiconductor layer and facing each other with the third polymer semiconductor layer interposed therebetween, the polymer chains of the third polymer semiconductor layer may be oriented parallel to a third channel length direction extending from the third source electrode to the third drain electrode, and the third thin film transistor may be in the stretchable region.

The first polymer semiconductor layer and the third polymer semiconductor layer may include a same polymer.

The first polymer semiconductor layer may include a plurality of semiconductor stripes extending perpendicularly to the first channel length direction and including the polymer, and the third polymer semiconductor layer may include a separate plurality of semiconductor stripes extending parallel to the third channel length direction and including the polymer.

The stretchable panel may further include a unit element electrically connected to the second thin film transistor, wherein the unit element may include a light emitting diode, a photovoltaic diode, or any combination thereof, and the unit element may be arranged in the non-stretchable region.

According to some example embodiments, an electronic device includes the aforementioned stretchable panel.

By including a strain sensor whose electrical characteristics are sensitive to stretching, local strain may be more effectively detected and thus may be more effectively compensated (e.g., by adjusting parameters of light emitted at the portions of the stretchable panel at which local strain is detected), thereby reducing, minimizing, or preventing performance degradation due to stretching of the stretchable panel.

### BRIEF DESCRIPTION OF THE DRAWINGS

FIG. 1 is a plan view schematically showing an example of a stretchable panel according to some example embodiments,

FIG. 2 is a perspective view schematically showing a strain sensor of the stretchable panel of FIG. 1 according to some example embodiments,

FIGS. 3, 4, and 5 are schematic views showing the portion “A” of the strain sensor of FIG. 2 according to some example embodiments,

FIG. 6 is a plan view schematically showing a stretchable panel according to some example embodiments,

FIG. 7 is a plan view of a stretchable panel according to some example embodiments, enlarged from the portion “B” of FIG. 6,

FIG. 8 is a cross-sectional view showing a unit element included in the stretchable panel illustrated in FIGS. 6 and 7 according to some example embodiments,

FIG. 9 is a perspective view schematically showing a thin film transistor included in the pixel circuit of the stretchable panel illustrated in FIGS. 6 and 7 according to some example embodiments,

FIGS. 10 and 11 are schematic diagrams showing the portion “C” of the thin film transistor of FIG. 9 according to some example embodiments,

FIG. 12 is a plan view of a stretchable panel according to some example embodiments, showing an enlarged portion of “B” in FIG. 6,

FIG. 13 is a cross-sectional view of the stretchable panel of FIG. 12 along cross-sectional view line XIII-XIII′ in FIG. 12, according to some example embodiments,

FIG. 14 is a perspective view schematically showing a second pixel circuit of the stretchable panel illustrated in FIGS. 12 and 13 according to some example embodiments,

FIGS. 15 and 16 are schematic views showing the portion “D” of the second pixel circuit of FIG. 14 according to some example embodiments,

FIG. 17 is a plan view schematically showing a stretchable panel according to some example embodiments,

FIG. 18 is a plan view showing the arrangement of the non-stretchable pattern in the stretchable panel of FIG. 17 according to some example embodiments,

FIG. 19 is a schematic view showing a skin-type stretchable display panel according to some example embodiments,

FIGS. 20, 21, 22, and 23 are schematic views showing examples of stretchable display panels according to some example embodiments, respectively,

FIGS. 24A, 24B, and 24C are schematic views showing skin-type sensor arrays according to some example embodiments,

FIG. 25 is a graph showing the change in current characteristics according to the stretching rate (strain) when the thin film transistor according to Example is stretched in the direction parallel to the source electrode-drain electrode direction (channel length direction) and in the direction perpendicular to the direction according to some example embodiments, and

FIG. 26 is a graph showing the change in current characteristics according to the stretching rate when the thin film transistor according to Reference Example 2 is stretched in the direction parallel to the source electrode-drain electrode direction (channel length direction) and in the direction perpendicular to the direction according to some example embodiments.

### DETAILED DESCRIPTION

Hereinafter, some example embodiments will be described in detail so that those of ordinary skill in the art may easily implement them. However, the actually applied structure may be implemented in several different forms and is not limited to the example embodiments described herein.

In the drawings, the thickness of layers, films, panels, regions, etc., are exaggerated for clarity.

It will be understood that when an element such as a layer, film, region, or substrate is referred to as being “on” another element, it may be directly on the other element or intervening elements may also be present. In contrast, when an element is referred to as being “directly on” another element, there are no intervening elements present.

As used herein, when a definition is not otherwise provided, “substituted” refers to replacement of hydrogen of a compound or a functional group by a substituent selected from a halogen atom, a hydroxy group, an alkoxy group, a nitro group, a cyano group, an amino group, an azido group, an amidino group, a hydrazino group, a hydrazono group, a carbonyl group, a carbamyl group, a thiol group, an ester group, a carboxyl group or a salt thereof, sulfonic acid group or a salt thereof, a phosphoric acid group or a salt thereof, a silyl group, a C1 to C20 alkyl group, a C2 to C20 alkenyl group, a C2 to C20 alkynyl group, a C6 to C30 aryl group, C7 to C30 arylalkyl group, C1 to C30 alkoxy group, a C1 to C20 heteroalkyl group, a C3 to C20 heteroaryl group, C3 to C20 heteroarylalkyl group, a C3 to C30 cycloalkyl group, a C3 to C15 cycloalkenyl group, a C6 to C15 cycloalkynyl group, a C3 to C30 heterocycloalkyl group, and any combination thereof.

Hereinafter, “polymer” includes a homopolymer, a copolymer, or any combination thereof.

Hereinafter, “combination” includes a mixture, a composite, or a stacked structure of two or more.

Hereinafter, a device, layer, element, region, or the like that is described as being “stretchable” will be understood to be elastic and/or configured to be elastic, such that the device, layer, element, region, or the like is configured to be elastically deformed (e.g., stretched, compressed, subjected to strain, etc.) such that the device, layer, element, region, or the like is configured to resume its same original shape after being deformed. For example, a stretchable device, layer, element, region, or the like as described herein may be capable of being elastically deformed such that the stretchable device, layer, element, region, or the like can resume, and does resume, an original shape after being stretched or compressed.

Hereinafter, a device, layer, element, region, or the like that is described as being “non-stretchable” will be understood to be non-elastic and/or not configured to be elastic, such that the device, layer, element, region, or the like is configured to not be elastically deformed (e.g., stretched, compressed, subjected to strain, etc.) such that the device, layer, element, region, or the like is configured to not resume its same original shape after being deformed. For example, a non-stretchable device, layer, element, region, or the like as described herein may not be able to be elastically deformed due to applied strain such that the non-stretchable device, layer, element, region, or the like cannot, and does not, resume an original shape after being stretched or compressed.

Hereinafter, a flexible device may be an electronic device formed on a substrate deformable by an external force, may include a stretchable device that may be stretched and restored by an external force.

It will be understood that elements and/or properties thereof (e.g., structures, surfaces, directions, or the like), which may be referred to as being “perpendicular,” “parallel,” or the like with regard to other elements and/or properties thereof (e.g., structures, surfaces, directions, or the like) may be “perpendicular,” “parallel,” or the like or may be “substantially perpendicular,” “substantially parallel,” or the like, respectively, with regard to the other elements and/or properties thereof.

Elements and/or properties thereof (e.g., structures, surfaces, directions, or the like) that are “substantially perpendicular” with regard to other elements and/or properties thereof will be understood to be “perpendicular” with regard to the other elements and/or properties thereof within manufacturing tolerances and/or material tolerances and/or have a deviation in magnitude and/or angle from “perpendicular,” or the like with regard to the other elements and/or properties thereof that is equal to or less than 10% (e.g., a. tolerance of ±10%).

Elements and/or properties thereof (e.g., structures, surfaces, directions, or the like) that are “substantially parallel” with regard to other elements and/or properties thereof will be understood to be “parallel” with regard to the other elements and/or properties thereof within manufacturing tolerances and/or material tolerances and/or have a deviation in magnitude and/or angle from “parallel,” or the like with regard to the other elements and/or properties thereof that is equal to or less than 10% (e.g., a. tolerance of ±10%).

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same.

It will be understood that elements and/or properties thereof described herein as being “substantially” the same and/or identical encompasses elements and/or properties thereof that have a relative difference in magnitude that is equal to or less than 10%. Further, regardless of whether elements and/or properties thereof are modified as “substantially,” it will be understood that these elements and/or properties thereof should be construed as including a manufacturing or operational tolerance (e.g., ±10%) around the stated elements and/or properties thereof.

While the term “same,” “equal” or “identical” may be used in description of some example embodiments, it should be understood that some imprecisions may exist. Thus, when one element is referred to as being the same as another element, it should be understood that an element or a value is the same as another element within a desired manufacturing or operational tolerance range (e.g., ±10%).

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the inventive concepts. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

As described herein, when an operation is described to be performed, or an effect such as a structure is described to be established “by” or “through” performing additional operations, it will be understood that the operation may be performed and/or the effect/structure may be established “based on” the additional operations, which may include performing said additional operations alone or in combination with other further additional operations.

As described herein, an element that is described to be “spaced apart” from another element, in general and/or in a particular direction (e.g., vertically spaced apart, laterally spaced apart, etc.) and/or described to be “separated from” the other element, may be understood to be isolated from direct contact with the other element, in general and/or in the particular direction (e.g., isolated from direct contact with the other element in a vertical direction, isolated from direct contact with the other element in a lateral or horizontal direction, etc.). Similarly, elements that are described to be “spaced apart” from each other, in general and/or in a particular direction (e.g., vertically spaced apart, laterally spaced apart, etc.) and/or are described to be “separated” from each other, may be understood to be isolated from direct contact with each other, in general and/or in the particular direction (e.g., isolated from direct contact with each other in a vertical direction, isolated from direct contact with each other in a lateral or horizontal direction, etc.). Similarly, a structure described herein to be between two other structures to separate the two other structures from each other may be understood to be configured to isolate the two other structures from direct contact with each other.

Hereinafter, a stretchable panel according to some example embodiments will be described with reference to the drawings.

A stretchable panel according to some example embodiments may include any panel having an array of elements including a plurality of unit elements that operate in an active matrix manner arranged on a substrate that is deformable by an external force. For example, the stretchable panel may include a flexible display panel, a stretchable display panel, a flexible sensor array panel, a stretchable sensor array panel, or any combination thereof, having flexible and/or stretchable characteristics.

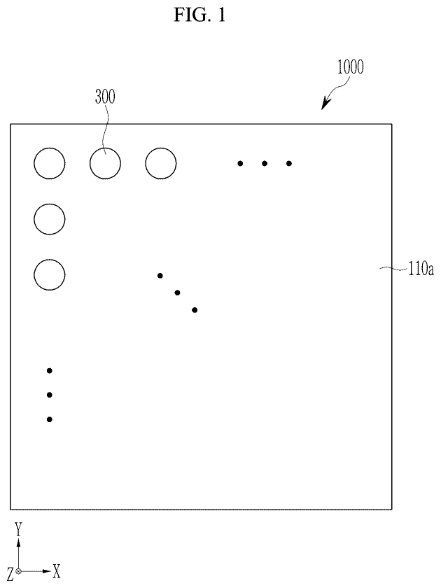

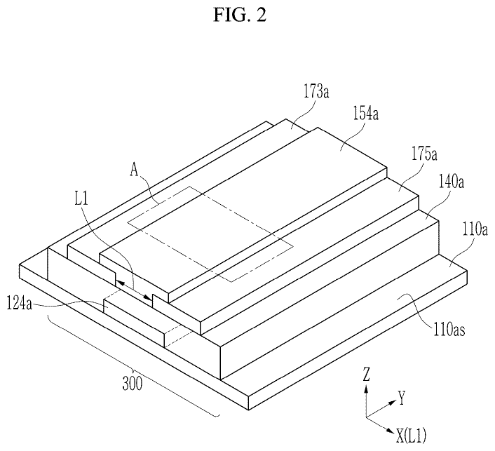

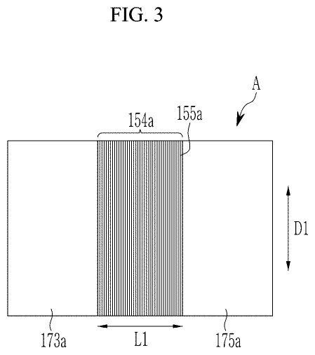

FIG. 1 is a plan view schematically showing an example of a stretchable panel according to some example embodiments, FIG. 2 is a perspective view schematically showing a strain sensor of the stretchable panel of FIG. 1 according to some example embodiments, and FIGS. 3, 4, and 5 are schematic views showing the portion “A” of the strain sensor of FIG. 2 according to some example embodiments.

Referring to FIG. 1, a stretchable panel 1000 according to some example embodiments includes a stretchable substrate 110a and a strain sensor 300 (e.g., one or more strain sensors 300).

The stretchable substrate 110a may have a particular (or, alternatively, predetermined) stretchability and may include an elastomer (hereinafter referred to as “first elastomer”) that may flexibly respond to external forces such as twisting, pressing, and pulling.

The first elastomer may include an organic elastomer (including an organic-inorganic elastomer), an inorganic elastomer-like material, or any combination thereof, having a relatively low elastic modulus (hereinafter referred to as the “first elastic modulus”). The first elastomer may include, for example, a polyorganosiloxane, a polymer including butadiene moieties, a polymer including urethane moieties, a polymer including acrylic moieties, a polymer including olefin moieties, or any combination thereof, for example, polydimethylsiloxane (PDMS), thermoplastic polyurethane (TPU), styrene-ethylene-butylene-styrene (SEBS), styrene-ethylene-propylene-styrene (SEPS), styrene-butadiene-styrene (SBS), styrene-isoprene-styrene (SIS), styrene-isobutylene-styrene (SIBS), or any combination thereof, but is not limited thereto. The inorganic elastomer-like material may include, for example, but not limited to, a ceramic having elasticity, a solid metal, a liquid metal, or any combination thereof.

The strain sensor 300 is disposed on (e.g., directly or indirectly on) the stretchable substrate 110a and may be configured to detect strain by indicating changes in electrical characteristics according to strain. The strain sensor 300 may be a stretchable strain sensor having a particular (or, alternatively, predetermined) stretchability, and thus may be stretched together with the stretchable substrate 110a when (e.g., based on) the stretchable substrate 110a is stretched, and may be located in a region where strain is concentrated due to stretching to sensitively detect the strain.

The strain sensor 300 may be, for example, a strain sensitive transistor, and may be configured to detect strain by, for example, a change in electrical characteristics according to the stretching of a polymer layer included in an active layer of the strain sensitive transistor.

Referring to FIGS. 2 and 3, the strain sensor 300 includes a first gate electrode 124a, a first gate insulating layer 140a, a first source electrode 173a, a first drain electrode 175a, and a first polymer semiconductor layer 154a.

The first gate electrode 124a may be made of (e.g., may at least partially comprise) a metal such as gold (Au), copper (Cu), nickel (Ni), aluminum (AI), molybdenum (Mo), chromium (Cr), tantalum (Ta), titanium (Ti), or any alloy thereof; a conductive nanostructure such as a nanowire or a nanotube; or any combination thereof, but is not limited thereto. For example, the first gate electrode 124a may be a stretchable electrode and may include, for example, a conductive layer having a plurality of microcracks.

The first gate insulating layer 140a may be formed on the whole surface of the stretchable substrate 110a (e.g., directly or indirectly on and/or overlapping an entirety of the upper surface 110as in the Z direction perpendicular to the upper surface 110as) and may be disposed between (e.g., directly or indirectly between) the first gate electrode 124a and the first polymer semiconductor layer 154a. The first gate insulating layer 140a may be made of (e.g., may at least partially comprise) an organic insulator, an inorganic insulator, and/or an organic-inorganic insulator, and may include, for example, a stretchable insulator. The first gate insulating layer 140a may have, for example, one layer or two or more layers. For example, the first gate insulating layer 140a may be made of (e.g., may at least partially comprise) an elastic polymer including, for example, polydimethylsiloxane (PDMS), thermoplastic polyurethane (TPU), styrene-ethylene-butylene-styrene (SEBS), styrene-ethylene-propylene-styrene (SEPS), styrene-butadiene-styrene (SBS), styrene-isoprene-styrene (SIS), styrene-isobutylene-styrene (SIBS), or any combination thereof, but is not limited thereto.

The first source electrode 173a may face the first drain electrode 175a with the first polymer semiconductor layer 154a interposed therebetween, and the first source electrode 173a and the first drain electrode 175a are each electrically connected to the first polymer semiconductor layer 154a. The first source electrode 173a and the first drain electrode 175a may be made of (e.g., may at least partially comprise) a metal such as gold (Au), copper (Cu), nickel (Ni), aluminum (AI), molybdenum (Mo), chromium (Cr), tantalum (Ta), titanium (Ti), or any alloy thereof; a conductive nanostructure such as a nanowire or a nanotube; or any combination thereof, but are not limited thereto. For example, the first source electrode 173a and the first drain electrode 175a may each independently be a stretchable electrode and may include, for example, a conductive layer having a plurality of microcracks.

The first polymer semiconductor layer 154a is overlapped with the first gate electrode 124a along the thickness direction (e.g., Z direction extending perpendicular to the upper surface 110as) of the stretchable substrate 110a. Referring to FIG. 3, the first polymer semiconductor layer 154a may be a stretchable semiconductor layer and may include a polymer (also referred to herein interchangeably as polymer chains 155a) oriented in one direction. The polymer (e.g., polymer chains 155a) may include a homopolymer, a copolymer, or any combination thereof including one or more repeating units, and may be, for example, a conjugated polymer. The polymer (e.g., polymer chains 155a) may be, for example, but is not limited to, a copolymer including repeating units including at least one electron donating moiety and repeating units including at least one electron accepting moiety.

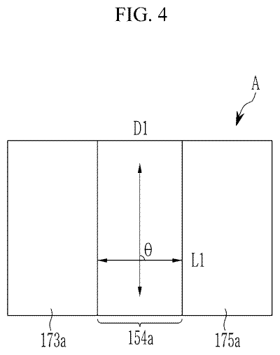

Referring to FIGS. 3 and 4, the polymer (e.g., polymer chains 155a) may be oriented along one direction (e.g., the first direction D1) within the first polymer semiconductor layer 154a, and a main chain (hereinafter referred to as “polymer chain,” and the terms “polymer” and “polymer chain” may be used interchangeably) in which repeating units of the polymer (e.g., polymer chains 155a) are connected in a single row may be oriented to intersect the first channel length direction L1 extending from the first source electrode 173a to the first drain electrode 175a. Here, the first channel length direction L1 may be a direction in which charge carriers (e.g., electrons) move from the first source electrode 173a to the first drain electrode 175a. As shown in at least FIG. 2, in some example embodiments the first source electrode 173a and the first drain electrode 175a may at least partially overlap each other in a horizontal direction extending in parallel with the stretchable substrate 110a (e.g., in parallel with the upper surface 110as thereof), for example the X direction as shown in FIG. 2, such that the first channel length direction L1 may be a direction extending in parallel with the stretchable substrate 110a (e.g., in parallel with the upper surface 110as thereof), for example extending in the X direction. However, it will be understood that relative arrangements of the first source electrode 173a and the first drain electrode 175a in relation to the stretchable substrate 110a, and thus the direction in which the first channel length direction L1 extends in relation to the stretchable substrate 110a, are not limited thereto.

In general, charge carriers (electrons) in a transistor may move along the polymer chains, and thus, when the channel length direction is parallel to the polymer chains, high charge mobility may be exhibited. Even if strain occurs in the channel length direction, it may not have any significant effect on the arrangement of the polymer chains, and thus the change in charge transfer characteristics may not be significant.

In contrast, since the polymer chains 155a of the first polymer semiconductor layer 154a are oriented to intersect the first channel length direction L1, the first channel length direction L1 and the polymer chains 155a may not be parallel (e.g., may not extend in parallel with each other), and thus the charge mobility may appear relatively low. In addition, when strain occurs in the first channel length direction L1, the gap between adjacent polymer chains 155a widens, so that a significant change in charge transfer characteristics according to the strain may occur, and the strain may be sensitively detected from this change in charge transfer characteristics according to the strain. As a result, the stretchable panel 1000 and/or a device including same (e.g., a stretchable device 2000) may have improved functionality by virtue of having an improved ability to detect strain at one or more portions of the stretchable panel 1000 (e.g., detect local strain at one or more limited portions of the stretchable panel 1000 as indicated by one or more strain sensors 300) with improved sensitivity. As a further result, the stretchable panel 1000 and/or a device including same (e.g., a stretchable device 2000) may have improved functionality by virtue of having an improved ability to responsively adjust display parameters of images and/or portions thereof displayed at the one or more limited portions of the stretchable panel 1000 (e.g., adjust brightness, intensity, etc. of light emitted at the one or more limited portions of the stretchable panel) to compensate for the detected local strain and thereby to reduce, minimize, or prevent degradation of display performance by the stretchable panel 1000 due to the detected local strain.

For example, referring to FIG. 4, the orientation direction D1 of the polymer chains 155a of the first polymer semiconductor layer 154a (e.g., the extension direction in which the polymer chains 155a each extend) may form a particular (or, alternatively, predetermined) angle (θ) with respect to the first channel length direction L1, and may be oriented at (e.g., the polymer chains 155a may extend in an orientation direction D1 that may form an angle of), for example, about 45 degrees to about 135 degrees with respect to the first channel length direction L1. Within the above range, the polymer chains 155a of the first polymer semiconductor layer 154a may be oriented at (e.g., the polymer chains 155a may have extend in an orientation direction D1 that may form an angle of), for example, about 60 to about 120 degrees, about 70 to about 110 degrees, about 80 to about 100 degrees, or about 85 to about 95 degrees with respect to the first channel length direction L1, and may be for example oriented perpendicularly or substantially perpendicularly (e.g., 90 degrees or about 90 degrees with respect to the first channel length direction L1). It will be understood that the terms “perpendicularly” and “perpendicular” may be used interchangeably herein.

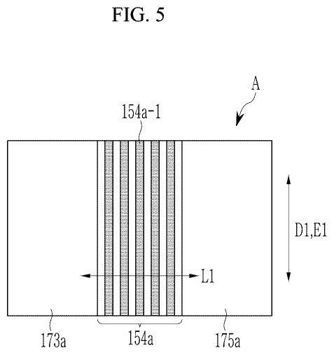

For example, referring to FIG. 5, the first polymer semiconductor layer 154a may include a plurality of semiconductor stripes 154a-1 extending in parallel along one direction (e.g., E1), and each semiconductor stripe 154a-1 may include at least a portion of the aforementioned polymer chains 155a. The extending direction E1 of the plurality of semiconductor stripes 154a-1 may be a direction intersecting the first channel length direction L1, for example, the extending direction E1 of each semiconductor stripe 154a-1 and the first channel length direction L1 may form an angle of about 45 degrees to about 135 degrees, and within the above range, may form an angle of about 60 degrees to about 120 degrees, about 70 degrees to about 110 degrees, about 80 degrees to about 100 degrees, or about 85 degrees to about 95 degrees, and may be perpendicular or substantially perpendicular (e.g., the extending direction E1 of each semiconductor stripe 154a-1 and the first channel length direction L1 may form an angle of 90 degrees or about 90 degrees). As shown in FIG. 5 extending direction E1 of each semiconductor stripe 154a-1 may be the same or substantially the same as the orientation direction D1 of the polymer chains 155a.

In this way, since the polymer chains 155a of the first polymer semiconductor layer 154a are oriented (e.g., extend in an orientation direction D1) so as to cross (e.g., perpendicularly or substantially perpendicularly, perpendicular or substantially perpendicular, etc.) with respect to the first channel length direction L1, the charge transfer characteristics (electrical characteristics) may change according to the change in the spacing between the polymer chains when strain occurs, and thus the strain may be sensitively detected. As a result, the stretchable panel 1000 and/or a device including same (e.g., a stretchable device 2000) may have improved functionality by virtue of having an improved ability to detect strain at one or more portions of the stretchable panel 1000 (e.g., detect local strain at one or more limited portions of the stretchable panel 1000 as indicated by one or more strain sensors 300) with improved sensitivity. As a further result, the stretchable panel 1000 and/or a device including same (e.g., a stretchable device 2000) may have improved functionality by virtue of having an improved ability to responsively adjust display parameters of images and/or portions thereof displayed at the one or more limited portions of the stretchable panel 1000 (e.g., adjust brightness, intensity, etc. of light emitted at the one or more limited portions of the stretchable panel) to compensate for the detected local strain and thereby to reduce, minimize, or prevent degradation of display performance by the stretchable panel 1000 due to the detected local strain. It will be understood that an element extending in an orientation direction D1 and/or an extending direction E1 may be understood to have a longitudinal axis extending in the orientation direction D1 and/or the extending direction E1.

Hereinafter, another example of a stretchable panel according to some example embodiments is described.

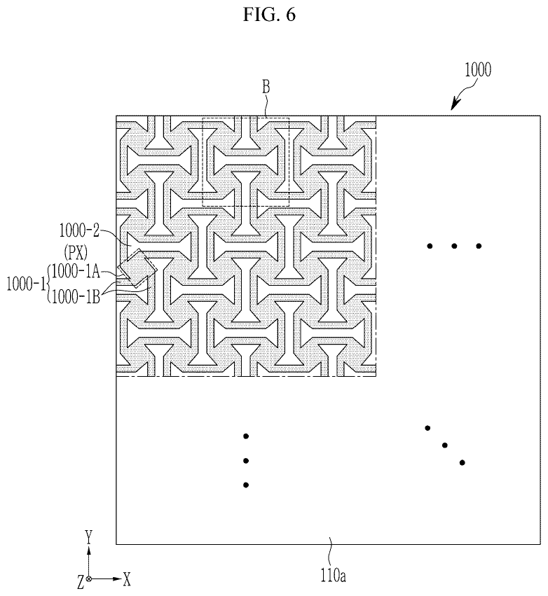

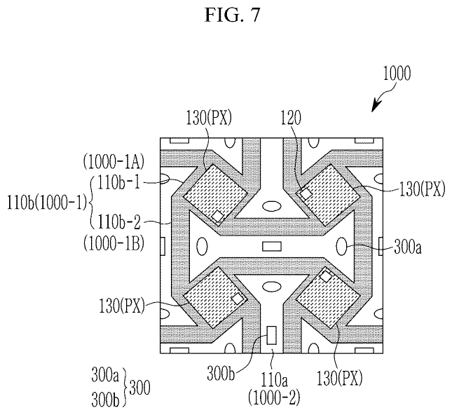

FIG. 6 is a plan view schematically showing a stretchable panel according to some example embodiments, and FIG. 7 is a plan view of a stretchable panel according to some example embodiments, enlarged from the portion “B” of FIG. 6.

Referring to FIGS. 6 and 7, the stretchable panel 1000 according to some example embodiments includes a region where the elastic modulus is different along the surface direction (e.g., XY direction) of the stretchable substrate 110a (also referred to herein interchangeably as an in-plane direction of the stretchable substrate 110a and which may extend in parallel with an upper surface 110as of the stretchable substrate 110a as shown in at least FIGS. 2, 9, and 13-14), and includes a stretchable region 1000-2 where the elastic modulus is relatively low and a non-stretchable region 1000-1 where the elastic modulus is relatively high (e.g., higher than the elastic modulus of the stretchable region 1000-2).

The stretchable region 1000-2 is a region capable of flexibly responding to an external force such as twisting, pressing, and pulling, and may be a region excluding the non-stretchable region 1000-1. The stretchable region 1000-2 may be a region in which the non-stretchable pattern 110b is not covered on the stretchable substrate 110a (e.g., a portion of the stretchable substrate 110a exposed from (e.g., not overlapped with) the non-stretchable pattern 110b in the Z direction extending perpendicular to the in-plane direction (e.g., XY direction) of the stretchable substrate) and may be relatively evenly disposed on the whole surface of the stretchable panel 1000 (e.g., may be uniformly or substantially uniformly distributed over the entire stretchable substrate 110a). For example, the stretchable region 1000-2 may include and/or may be defined by a particular portion of the stretchable substrate 110a that is exposed from one or more non-stretchable patterns 110b in a thickness direction of the stretchable substrate 110a (e.g., the Z direction as shown).

The elastic modulus of the stretchable region 1000-2 may be the same or substantially the same as the elastic modulus of the stretchable substrate 110a. The stretchable substrate 110a may include an elastomer (e.g., referred to herein interchangeably as a first elastomer) having a relatively low elastic modulus as described above, and the elastic modulus of the elastomer may be, for example, about 100 Pa to about 109 Pa, but is not limited thereto. The elastomer may include, for example, polyorganosiloxane, a polymer including a butadiene moiety, a polymer including a urethane moiety, a polymer including an acrylic moiety, a polymer including an olefin moiety, or a combination thereof, and may be for example polydimethylsiloxane (PDMS), thermoplastic polyurethane (TPU), styrene-ethylene-butylene-styrene (SEBS), styrene-ethylene-propylene-styrene (SEPS), styrene-butadiene-styrene (SBS), styrene-isoprene-styrene (SIS), styrene-isobutylene-styrene (SIBS), or any combination thereof, but is not limited thereto. The inorganic elastomer-like material may include, for example, a ceramic having elasticity, a solid metal having elasticity, a liquid metal having elasticity, or any combination thereof, but not limited thereto.

The stretchable region 1000-2 may be surrounded and isolated (e.g., in the in-plane direction, for example in the XY direction) by the non-stretchable region 1000-1, but example embodiments are not limited thereto, and on the contrary, the non-stretchable region 1000-1 may be surrounded and isolated (e.g., in the XY direction) by the stretchable region 1000-2.

The non-stretchable region 1000-1 may be a region in which resistance to external force such as twisting, pressing, and pulling is relatively high, so that it may be not substantially deformed by the external force or a deformation degree may be very small. That is, the non-stretchable region 1000-1 may include a stretch resistance region with very low stretchability due to a large resistance to stretching, in addition to a region with no stretchability at all. The non-stretchable region 1000-1 may include a non-stretchable pattern 110b. While example embodiments of the stretchable panel 1000 are described herein to include a non-stretchable pattern 110b, it will be understood that the non-stretchable pattern 110b may include multiple non-stretchable patterns, and in some example embodiments a stretchable panel 1000 may include multiple non-stretchable patterns 110b. The non-stretchable pattern 110b may include an organic, inorganic, and/or organic-inorganic material having a high elastic modulus.

The non-stretchable region 1000-1 may be a region in which the non-stretchable pattern 110b having a high elastic modulus is covered on the stretchable substrate 110a (e.g., covering at least a portion of the stretchable substrate 110a in the Z direction) as will be described later, and accordingly the non-stretchable region 1000-1 may have the same or substantially the same planar shape as the non-stretchable pattern 110b.

The elastic modulus of the non-stretchable region 1000-1 may be determined by (e.g., may be based on) the elastic modulus of the non-stretchable pattern 110b. For example, the elastic modulus of the non-stretchable pattern 110b may be about 100 times or more, within the above range, about 300 times or more, about 500 times or more, or about 1000 times or more, and within the above range, about 100 times to about 10⁸ times, about 500 times to about 10⁸ times, about 1000 times to about 10⁸ times, about 100 times to about 10⁷ times, about 500 times to about 10⁷ times, or about 1000 times to about 10⁷ times, higher than that of the stretchable substrate 110a. For example, the elastic modulus of the non-stretchable pattern 110b may be about 10⁴ Pa to about 10¹² Pa, but is not limited thereto. Due to the high elastic modulus of the non-stretchable pattern 110b, the non-stretchable region 1000-1 may not be substantially stretched or deformed (e.g., may remain rigid or substantially rigid) even if the stretchable substrate 110a is stretched in a particular (or, alternatively, predetermined) direction.

The non-stretchable pattern 110b may include an organic material, an inorganic material, an organic-inorganic material, or any combination thereof having a relatively high elastic modulus, and may include, for example, a non-stretchable material but a flexible material, such as polycarbonate, polymethyl methacrylate, polyethylene terephthalate, polyethylene naphthalate, polyimide, polyamide, polyamideimide, polyether sulfone, or any combination thereof, but is not limited thereto.

The non-stretchable pattern 110b may be formed by, for example, coating or depositing a material (e.g., an organic material) with a relatively high elastic modulus on the stretchable substrate 110a and partially removing it (e.g., the material) by, for example, etching, to leave the non-stretchable pattern 110b only in the portion corresponding to the non-stretchable region 1000-1. However, the present inventive concepts are not limited thereto, and the non-stretchable region 1000-1 and the stretchable region 1000-2 having different elastic moduli may be implemented by forming the non-stretchable pattern 110b on the stretchable substrate 110a in various ways.

The non-stretchable pattern 110b may include a plurality of planar patterns 110b-1 and a plurality of bridge patterns 110b-2. A plurality of planar patterns 110b-1 may be repeatedly disposed on the stretchable substrate 110a to define a plurality of planar regions 1000-1A (e.g., island-shaped non-stretchable regions) of the non-stretchable region 1000-1, and a plurality of bridge patterns 110b-2 may be repeatedly disposed on the stretchable substrate 110a to define a plurality of bridge regions 1000-1B of the non-stretchable region 1000-1 (e.g., one or more of the bridge regions 1000-1B connecting adjacent planar regions 1000-1A).

The plurality of planar regions 1000-1A may be regions occupied by a plurality of pixels PX of the stretchable panel 1000, and the plurality of pixels PX may be repeatedly arranged along rows and/or columns. Each pixel PX may include a plurality of subpixels, and the plurality of subpixels included in each pixel PX may have an arrangement such as 3×1, 2×2, 3×3, or 4×4, but example embodiments are not limited thereto. The arrangement of the plurality of pixels PXs (or subpixels) may be the same as that of the unit element 130 to be described later, and may be, for example, a Bayer matrix, a PenTile matrix, and/or a diamond matrix, but is not limited thereto. In the following description, a pixel and a subpixel may be used interchangeably.

The planar pattern 110b-1 defining each planar region 1000-1A may have a particular (or, alternatively, predetermined) area, and a unit element 130, which will be described later, and at least a portion of a pixel circuit 120 that drives the unit element 130 may be disposed thereon. As described herein, the pixel circuit 120 may include a plurality of pixel circuits 120, and the unit element 130 may include a plurality of unit elements 130, where the plurality of pixel circuits 120 are configured to independently operate separate, respective unit elements 130 of the plurality of unit elements 130. Since each unit element 130 is disposed on each planar pattern 110b-1 (e.g., the unit elements 130 may be on separate, respective planar patterns 110b-1), the size (area) of each planar pattern 110b-1 may be larger than the size (area) of each unit element 130.

The plurality of bridge regions 1000-1B may be defined by bridge patterns 110b-2, and each bridge pattern 110b-2 may connect adjacent planar patterns 110b-1. The bridge pattern 110b-2 may have, for example, a linear shape, and wirings may be arranged thereon.

The arrangements of the planar region 1000-1A and the bridge region 1000-1B may be variously modified according to the arrangements of the plurality of unit elements 130 and the wirings, but when the stretchable substrate 110a is stretched, it may be arranged in a geometric pattern so that a three-dimensional deformation may occur. The geometric pattern may include, for example, a kirigami pattern including cut lines, but is not limited thereto. The geometric pattern of the non-stretchable region 1000-1 is such that when an external force such as twisting, pressing, or pulling in a particular (or, alternatively, predetermined) direction is applied to the stretchable panel 1000, even if the non-stretchable region 1000-1 is not flexibly stretched by an external force like the stretchable substrate 110a, it may enable three-dimensional deformation of the stretchable panel 1000.

The stretchable panel 1000 according to some example embodiments includes a strain sensor 300, a unit element 130, and a pixel circuit 120. The strain sensor 300 may be in the stretchable region 1000-2 and the unit element 130 and pixel circuit 120 may be in the non-stretchable region 1000-1.

The strain sensor 300 may be a stretchable strain sensor as described above, and may be disposed in a region where a large amount of strain is applied due to stretching to sensitively detect the strain. The strain sensor 300 may be a strain-sensitive transistor including a first gate electrode 124a, a first gate insulating layer 140a, a first source electrode 173a, a first drain electrode 175a, and a first polymer semiconductor layer 154a, as illustrated in FIG. 2. The polymer chains 155a of the first polymer semiconductor layer 154 may be oriented to intersect (for example, substantially perpendicularly) with the first channel length direction L1, so that when strain occurs in the first channel length direction L1, the gap between adjacent polymer chains widens, and thus a large change in charge transfer characteristics according to the strain may occur, and the strain may be sensitively detected from the change in charge transfer characteristics according to the strain. The detailed explanation is as described above. As a result, the stretchable panel 1000 and/or a device including same (e.g., a stretchable device 2000) may have improved functionality by virtue of having an improved ability to detect strain at one or more portions of the stretchable panel 1000 (e.g., detect local strain at one or more limited portions of the stretchable panel 1000 as indicated by one or more strain sensors 300) with improved sensitivity. As a further result, the stretchable panel 1000 and/or a device including same (e.g., a stretchable device 2000) may have improved functionality by virtue of having an improved ability to responsively adjust display parameters of images and/or portions thereof displayed at the one or more limited portions of the stretchable panel 1000 (e.g., adjust brightness, intensity, etc. of light emitted at the one or more limited portions of the stretchable panel) to compensate for the detected local strain and thereby to reduce, minimize, or prevent degradation of display performance by the stretchable panel 1000 due to the detected local strain.

The strain sensor 300 may be evenly distributed in the stretchable region 1000-2 (e.g., a plurality of strain sensors 300 may be uniformly or substantially uniformly distributed in the stretchable region 1000-2) and may include, for example, first and second strain sensors 300a and 300b that are disposed separately from each other. The first and second strain sensors 300a and 300b may be arranged in different directions to correspond to various stretching directions, and accordingly, the first channel length directions L1 of the first and second strain sensors 300a and 300b may be different from each other. By including the first and second strain sensors 300a and 300b arranged in different directions in this way, it is possible to evaluate in which direction the strain is applied depending on the location. As a result, the stretchable panel 1000 and/or a device including same (e.g., a stretchable device 2000) may have improved functionality by virtue of having an improved ability to detect strain, including the directions of such strain, at one or more portions of the stretchable panel 1000 (e.g., detect local strain at one or more limited portions of the stretchable panel 1000 as indicated by one or more strain sensor 300) with improved sensitivity. As a further result, the stretchable panel 1000 and/or a device including same (e.g., stretchable device 2000) may have improved functionality by virtue of having an improved ability to responsively adjust display parameters of images and/or portions thereof displayed at the one or more limited portions of the stretchable panel 1000 (e.g., adjust brightness, intensity, etc. of light emitted at the one or more limited portions of the stretchable panel) to compensate for the detected local strain and thereby to reduce, minimize, or prevent degradation of display performance by the stretchable panel 1000 due to the detected local strain.

The unit element 130 may be disposed in each planar region 1000-1A of the non-stretchable region 1000-1 and may be disposed on the planar pattern 110b-1 of the non-stretchable pattern 110b described above. For example, where the unit element 130 includes a plurality of unit elements 130 and the non-stretchable region 1000-1 includes a plurality of planar regions 1000-1A, each separate unit element 130 of the plurality of unit elements 130 may be in a separate planar region 1000-1A of the non-stretchable region 1000-1. Each unit element 130 included in each planar region 1000-1A of the non-stretchable region 1000-1 may be, for example, a light emitting diode such as an organic light emitting diode, an inorganic light emitting diode, a quantum dot light emitting diode, a micro light emitting diode, or a perovskite light emitting diode, or a photoelectric conversion diode such as an organic photoelectric conversion diode, an inorganic photoelectric conversion diode, or an organic/inorganic photoelectric conversion diode, and may be the same or different from each other.

As an example, each unit element 130 may be a light emitting diode configured to independently display red light, green light, blue light, or any combination thereof.

As an example, each unit element 130 may be a photoelectric conversion diode configured to selectively absorb light of red wavelengths, green wavelengths, blue wavelengths, infrared wavelengths, or any combination and convert the absorbed light into an electrical signal.

As an example, a portion of the unit element 130 may be a light emitting diode and a portion (e.g., a separate portion) of the unit element 130 may be a photoelectric conversion diode.

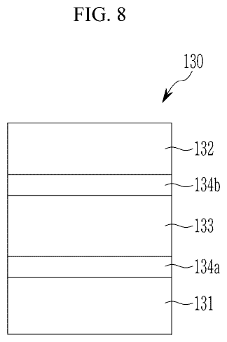

FIG. 8 is a cross-sectional view showing a unit element included in the stretchable panel illustrated in FIGS. 6 and 7 according to some example embodiments.

Referring to FIG. 8, the unit element 130 (e.g., each separate unit element 130) may be a light emitting diode or a photoelectric conversion diode and may include an anode 131; a cathode 132; an active layer 133 between the anode 131 and the cathode 132; and optionally one or both of auxiliary layers 134a and 134b between the anode 131 and the active layer 133 and/or between the cathode 132 and the active layer 133.

At least one of the anode 131 or the cathode 132 may be a light transmitting electrode. For example, the anode 131 may be a light transmitting electrode and the cathode 132 may be a reflective electrode. For example, the anode 131 may be a reflective electrode and the cathode 132 may be a light transmitting electrode. The light-transmitting electrode may be made of (e.g., may at least partially comprise), for example, a transparent conductor such as indium tin oxide (ITO) or indium zinc oxide (IZO) or a single-layer with a thin thickness or multi-layer metal thin film. When one of the anode 131 or the cathode 132 is an opaque electrode, the opaque electrode may be made of an opaque conductor such as aluminum (Al). For example, the anode 131 and the cathode 132 may each be a light transmitting electrode. At least one of the anode 131 or the cathode 132 may be a stretchable electrode. the stretchable electrode may include, for example, a stretchable conductor or may have a stretchable shape such as a wavy shape, a pleat shape, a pop-up shape, or a non-planar mesh shape. The stretchable electrode may have, for example, a plurality of microcracks, and since the plurality of microcracks are separated from each other like small holes, flexibility may be provided to the stretchable electrode by extending along the stretching direction during stretching while maintaining the electrical transport path in the stretchable electrode.

The active layer 133 may be a light emitting layer or a photoelectric conversion layer.

The light emitting layer may be configured to emit light in a red wavelength region, a green wavelength region, a blue wavelength region, an infrared wavelength region, or any combination thereof, and may include, for example, an organic light emitting layer, an inorganic light emitting layer (including a quantum dot light emitting layer), an organic/inorganic light emitting layer, or any combination thereof. The light emitting layer may include at least one host material and at least one dopant.

The photoelectric conversion layer may be configured to absorb light in a red wavelength region, a green wavelength region, a blue wavelength region, an infrared wavelength region, or any combination thereof, and may be configured to convert the absorbed light into an electrical signal, and may be an organic photoelectric conversion layer, an inorganic photoelectric conversion layer, an organic/inorganic photoelectric conversion layer, or any combination thereof. The photoelectric conversion layer may include a p-type semiconductor and an n-type semiconductor, and the p-type semiconductor and the n-type semiconductor may form a pn junction.

The active layer 133 (e.g., the photoelectric conversion layer) may include a first compound as the p-type semiconductor or the n-type semiconductor.

The first compound may be a light absorber capable of selectively absorbing light of a particular (or, alternatively, predetermined) wavelength band among visible ray regions. For example, the first compound may selectively absorb light in a green wavelength band. For example, the maximum absorption wavelength (λₘₐₓ) of the first compound may be between about 500 nm to 600 nm and may have an energy bandgap of about 2.0 to 2.5 eV.

For example, the first compound may be a p-type semiconductor that may be an organic material having a core structure including an electron donating moiety EDM, a TT-conjugated linking moiety LM, and an electron accepting moiety EAM according to Chemical Formula 1.

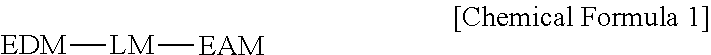

In Chemical Formula 1,
EDM may be an electron donating moiety,
EAM may be an electron accepting moiety, and
LM may be a pi conjugated linking moiety to link the electron donating moiety and the electron accepting moiety.

For example, the active layer 133 (e.g., a photoelectric conversion layer or a light emitting layer) may include a first compound as the p-type semiconductor that may be represented by Chemical Formula 2.

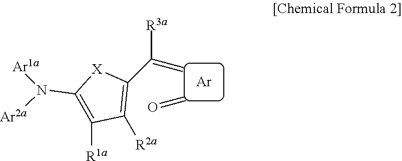

In Chemical Formula 2,
X may be O, S, Se, Te, SO, SO₂, CR^{b}R^{c}, or SiR^{d}R^{e},
Ar may be a substituted or unsubstituted C6 to C30 arylene group, a substituted or unsubstituted C3 to C30 heterocyclic group, or a fused ring of two or more selected therefrom,
Ar^{1a} and Ar^{2a} may each independently be a substituted or unsubstituted C6 to C30 aryl(ene) group or a substituted or unsubstituted C3 to C30 heteroaryl(ene) group,
R^{1a} to R^{3a} and R^{b} to R^{e} may each independently be hydrogen, a substituted or unsubstituted C1 to C30 alkyl group, a substituted or unsubstituted C1 to C30 alkoxy group, a substituted or unsubstituted C6 to C30 aryl group, a substituted or unsubstituted C3 to C30 heteroaryl group, a halogen, a cyano group, or any combination thereof, and
Ar^{1a}, Ar^{2a}, R^{1a}, and R^{2a} may each independently be present, or two adjacent ones may be linked to each other to form a ring.

For example, Ar^{1a} and Ar^{2a} may each independently be a substituted or unsubstituted phenyl group, a substituted or unsubstituted naphthyl group, a substituted or unsubstituted anthracenyl group, a substituted or unsubstituted phenanthrenyl group, a substituted or unsubstituted pyridinyl group, a substituted or unsubstituted pyridazinyl group, a substituted or unsubstituted pyrimidinyl group, a substituted or unsubstituted pyrazinyl group, a substituted or unsubstituted quinolinyl group, a substituted or unsubstituted isoquinolinyl group, a substituted or unsubstituted naphthyridinyl group, a substituted or unsubstituted cinnolinyl group, a substituted or unsubstituted quinazolinyl group, a substituted or unsubstituted phthalazinyl group, a substituted or unsubstituted benzotriazinyl group, a substituted or unsubstituted pyridopyrazinyl group, a substituted or unsubstituted pyridopyrimidinyl group, or a substituted or unsubstituted pyridopyridazinyl group.

For example, Ar^{1a} and Ar^{2a} may be linked to each other to form a ring.

For example, Ar^{2a} and R^{1a} may be linked to each other to form a ring.

For example, the active layer 133 (e.g., the photoelectric conversion layer) may include an n-type semiconductor, in addition to a first compound that is the p-type semiconductor, that may be fullerene or a fullerene derivative, thiophene or a thiophene derivative, or any combination thereof, but is not limited thereto.

As described herein, examples of the fullerene may include C60, C70, C76, C78, C80, C82, C84, C90, C96, C240, C540, a mixture thereof, a fullerene nanotube, and the like. The fullerene derivative may refer to compounds of these fullerenes having a substituent thereof. The fullerene derivative may include a substituent such as an alkyl group (e.g., C1 to C30 alkyl group), an aryl group (e.g., C6 to C30 aryl group), a heterocyclic group (e.g., C3 to C30 heterocycloalkyl group), and the like. Examples of the aryl groups and heterocyclic groups may be a benzene ring, a naphthalene ring, an anthracene ring, a phenanthrene ring, a fluorene ring, a triphenylene ring, a naphthacene ring, a biphenyl ring, a pyrrole ring, a furan ring, a thiophene ring, an imidazole ring, an oxazole ring, a thiazole ring, a pyridine ring, a pyrazine ring, a pyrimidine ring, a pyridazine ring, an indolizine ring, an indole ring, a benzofuran ring, a benzothiophene ring, a isobenzofuran ring, a benzimidazole ring, a imidazopyridine ring, a quinolizidine ring, a quinoline ring, a phthalazine ring, a naphthyridine ring, a quinoxaline ring, an isoquinoline ring, a carbazole ring, a phenanthridine ring, an acridine ring, a phenanthroline ring, a thianthrene ring, a chromene ring, an xanthene ring, a phenoxazine ring, a phenoxathiin ring, a phenothiazine ring, or a phenazine ring.

The thiophene derivative may be for example represented by Chemical Formula 3 or Chemical Formula 4, but is not limited thereto.

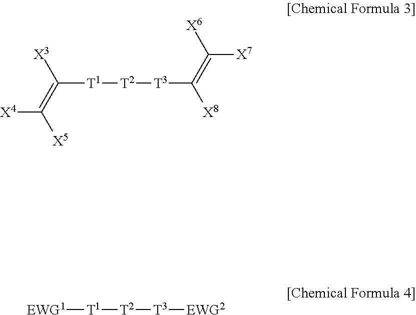

In Chemical Formulas 3 and 4,
T1, T2, and T3 may be aromatic rings including substituted or unsubstituted thiophene moieties,
T1, T2, and T3 may each independently be present or may be fused to each other,
X3 to X8 may each independently be hydrogen, deuterium, a substituted or unsubstituted C1 to C30 alkyl group, a substituted or unsubstituted C1 to C30 alkoxy group, a substituted or unsubstituted C6 to C30 aryl group, a substituted or unsubstituted C3 to C30 heterocyclic group, a cyano group, or any combination thereof, and
EWG1 and EWG2 may each independently be an electron withdrawing group, for example, a cyano group or a cyano-containing group.

For example, in Chemical Formula 3, at least one of X3 to X8 may be an electron withdrawing group, for example, a cyano group or a cyano-containing group.

The auxiliary layers 134a and 134b may be, for example, charge auxiliary layers, and may be, for example, a hole transport layer, a hole injection layer, an electron blocking layer, an electron transport layer, an electron injection layer, a hole blocking layer, or any combination thereof, but example embodiments are not limited thereto.

The auxiliary layers 134a and 134b may include, for example, an organic material, an inorganic material, or an organic/inorganic material. The organic material may be an organic compound having hole or electron characteristics, and the inorganic material may be, for example, a metal oxide such as molybdenum oxide, tungsten oxide, or nickel oxide.

The hole transport layer (HTL) may include one selected from, for example, a poly(3,4-ethylenedioxythiophene):poly(styrenesulfonate) (PEDOT:PSS), a polyaryl amine, a poly(N-vinylcarbazole), a polyaniline, a polypyrrole, an N,N,N′,N′-tetrakis(4-methoxyphenyl)-benzidine (TPD), a 4-bis [N-(1-naphthyl)-N-phenyl-amino]biphenyl (α-NPD), an m-MTDATA, a 4,4′,4″-tris(N-carbazolyl)-triphenylamine (TCTA), and any combination thereof, but is not limited thereto.

The electron blocking layer (EBL) may include one selected from, for example, a poly(3,4-ethylenedioxythiophene):poly(styrenesulfonate), (PEDOT:PSS), a poly Arylamine, a poly(N-vinylcarbazole), a polyaniline, a polypyrrole, an N, N,N′,N′-tetrakis (4-methoxyphenyl)-benzidine (TPD), a 4-bis [N-(1-naphthyl)-N-phenyl-amino]biphenyl (α-NPD), an m-MTDATA, a 4,4′,4″-tris(N-carbazolyl)-triphenylamine (TCTA), and any combination thereof, but is not limited thereto.

The electron transport layer (ETL) may include one selected from, for example, a 1,4,5,8-naphthalene-tetracarboxylic dianhydride (NTCDA), a bathocuproine (BCP), an LiF, an Alq3, a Gaq3, an Inq3, a Znq2, a Zn(BTZ)2, a BeBq2 and any combination thereof, but is not limited thereto.

The hole blocking layer (HBL) may include one selected from, for example, a 1,4,5,8-naphthalene-tetracarboxylic dianhydride (NTCDA), bathocuproine (BCP), an LiF, an Alq3, a Gaq3, an Inq3, a Znq2, a Zn(BTZ)2, a BeBq2 and any combination thereof, but is not limited thereto.

Any one of the auxiliary layers 134a and 134b may be omitted.

Each unit element 130 may be independently controlled and/or driven by each pixel circuit 120.

The pixel circuit 120 may be repeatedly arranged on the stretchable substrate 110a and may be arranged around each pixel PX to independently control and/or drive each pixel PX. The pixel circuit 120 may include elements necessary to independently control and/or drive each pixel (or subpixel), and may include, for example, a plurality of thin film transistors (TFTs) and capacitors.

The plurality of thin film transistors (TFT) may include at least one switching thin film transistor (switching TFT) and at least one driving thin film transistor (driving TFT).

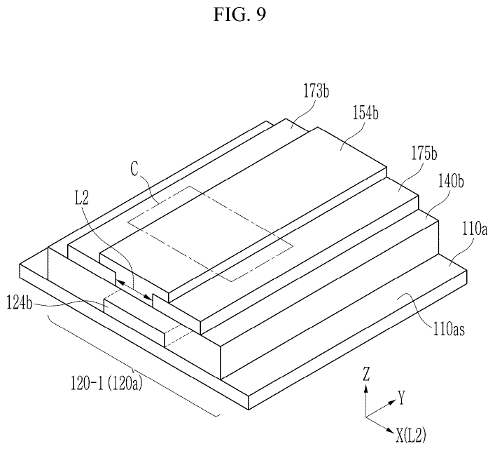

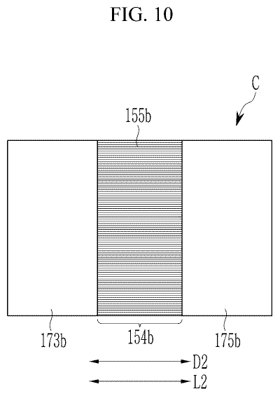

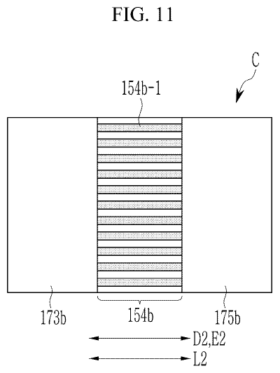

FIG. 9 is a perspective view schematically showing a thin film transistor included in the pixel circuit 120 of the stretchable panel 1000 illustrated in FIGS. 6 and 7 according to some example embodiments, and FIGS. 10 and 11 are schematic diagrams showing the portion “C” of the thin film transistor of FIG. 9 according to some example embodiments.

Referring to FIGS. 9 and 10, a thin film transistor 120-1 included in a pixel circuit 120 includes a second gate electrode 124b, a second gate insulating layer 140b, a second source electrode 173b, a second drain electrode 175b, and a second polymer semiconductor layer 154b.

The second gate electrode 124b may be made of (e.g., may at least partially comprise) a metal such as gold (Au), copper (Cu), nickel (Ni), aluminum (AI), molybdenum (Mo), chromium (Cr), tantalum (Ta), titanium (Ti), or any alloy thereof; a conductive nanostructure such as a nanowire or a nanotube; or any combination thereof, but is not limited thereto. For example, the second gate electrode 124b may be a stretchable electrode and may include, for example, a conductive layer having a plurality of microcracks.

The second gate insulating layer 140b is formed on the whole surface of the stretchable substrate 110a (e.g., directly or indirectly on and/or overlapping an entirety of the upper surface 110as in the Z direction perpendicular to the upper surface 110as) and may be disposed between (e.g., directly or indirectly between) the second gate electrode 124b and the second polymer semiconductor layer 154b. The second gate insulating layer 140b may be made of (e.g., may at least partially comprise) an organic insulator, an inorganic insulator, and/or an organic-inorganic insulator, and may include, for example, a stretchable insulator. The second gate insulating layer 140b may have, for example, one layer or two or more layers. For example, the second gate insulating layer 140b may be made of (e.g., may at least partially comprise) an elastic polymer including, for example, polydimethylsiloxane (PDMS), thermoplastic polyurethane (TPU), styrene-ethylene-butylene-styrene (SEBS), styrene-ethylene-propylene-styrene (SEPS), styrene-butadiene-styrene (SBS), styrene-isoprene-styrene (SIS), styrene-isobutylene-styrene (SIBS), or any combination thereof, but is not limited thereto.

The second source electrode 173b and the second drain electrode 175b face each other with the second polymer semiconductor layer 154b interposed therebetween, and are electrically connected to the second polymer semiconductor layer 154b. The second source electrode 173b and the second drain electrode 175b may be made of (e.g., may at least partially comprise) a metal such as gold (Au), copper (Cu), nickel (Ni), aluminum (AI), molybdenum (Mo), chromium (Cr), tantalum (Ta), titanium (Ti), or an alloy thereof; a conductive nanostructure such as a nanowire or a nanotube; or any combination thereof, but are not limited thereto. For example, the second source electrode 173b and the second drain electrode 175b may each independently be a stretchable electrode and may include, for example, a conductive layer having a plurality of microcracks.

The second polymer semiconductor layer 154b is overlapped with the second gate electrode 124b along the thickness direction (e.g., Z direction extending perpendicular to the upper surface 110as) of the stretchable substrate 110a. The second polymer semiconductor layer 154b may include a polymer (polymer chain) 155b oriented in one direction, and the orientation direction D2 of the polymer chain 155b may be parallel or substantially parallel to the second channel length direction L2 extending from the second source electrode 173b to the second drain electrode 175b. Herein, the second channel length direction L2 may be a direction in which charge carriers (e.g., electrons) move from the second source electrode 173b to the second drain electrode 175b when voltage is applied to the second gate electrode 124b. As shown in at least FIG. 9, in some example embodiments the second source electrode 173b and the second drain electrode 175b may at least partially overlap each other in a horizontal direction extending in parallel with the stretchable substrate 110a (e.g., in parallel with the upper surface 110as thereof), for example the X direction as shown in FIG. 9, such that the second channel length direction L2 may be a direction extending in parallel with the stretchable substrate 110a (e.g., in parallel with the upper surface 110as thereof), for example extending in the X direction. However, it will be understood that relative arrangements of the second source electrode 173b and the second drain electrode 175b in relation to the stretchable substrate 110a, and thus the direction in which the second channel length direction L2 extends in relation to the stretchable substrate 110a, are not limited thereto.

In this way, since the polymer chains 155b of the second polymer semiconductor layer 154b are oriented parallel or substantially parallel to the second channel length direction L2, when voltage is applied to the second gate electrode 124b, the charge carriers (electrons) of the thin film transistor 120-1 may more effectively move along the polymer chains 155b, thereby exhibiting higher charge mobility. In addition, even if strain occurs in the second channel length direction L2, it does not significantly affect the arrangement of the polymer chains 155b, and thus more stable charge transfer characteristics may be exhibited. As a result, the stretchable panel 1000 may have improved functionality by virtue of the pixel circuit(s) 120 (e.g., first pixel circuit 120a) of the stretchable panel 1000 being configured to exhibit more stable charge transfer characteristics and/or higher charge mobility to reduce, minimize, or prevent degradation of display performance by the stretchable panel 1000 due to local strain in the stretchable panel 1000.

For example, referring to FIG. 11, the second polymer semiconductor layer 154b may include a plurality of semiconductor stripes 154b-1 extending in parallel along one direction (e.g., E2), and each semiconductor stripe 154b-1 may include at least a portion of the aforementioned polymer chains 155b. The extending direction E2 of the plurality of semiconductor stripes 154b-1 may be parallel or substantially parallel to the second channel length direction L2, which may be the same or substantially the same as the orientation direction D2 of the polymer chains 155b.

For example, the strain sensor 300 and the thin film transistor 120-1 may be formed simultaneously through the same process. Accordingly, a stretchable panel 1000 including a strain sensor 300 may be manufactured without an additional process.

Accordingly, the first gate electrode 124a and the second gate electrode 124b may include the same conductor, the first polymer semiconductor layer 154a and the second polymer semiconductor layer 154b may include the same polymer, and the first and second source electrodes 173a and 173b and the first and second drain electrodes 175a and 175b may include the same conductor. For example, the first polymer semiconductor layer 154a and the second polymer semiconductor layer 154b may include the same polymer, but only the orientation direction of the polymer may be different from each other.

Hereinafter, another example of a stretchable panel according to some example embodiments will be described.

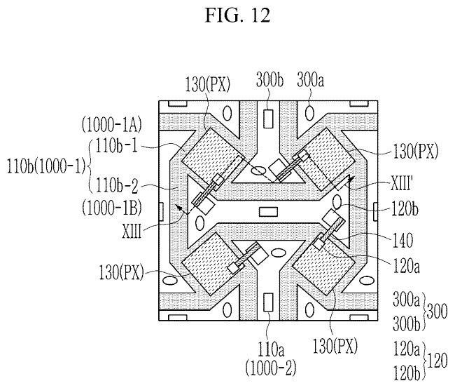

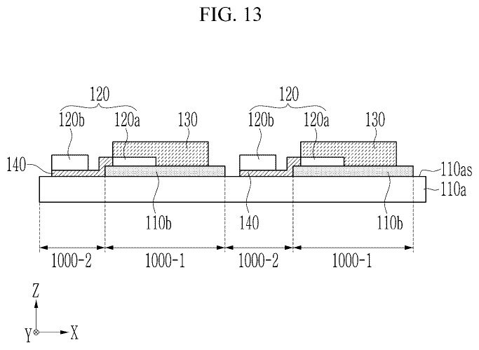

FIG. 12 is a plan view of a stretchable panel according to some example embodiments, showing an enlarged portion of “B” in FIG. 6 and FIG. 13 is a cross-sectional view of the stretchable panel of FIG. 12 along cross-sectional view line XIII-XIII′ in FIG. 12 according to some example embodiments.

Referring to FIG. 12, the stretchable panel 1000 according to some example embodiments, for example the example embodiments as shown in FIGS. 6-7, includes the stretchable region 1000-2 and the non-stretchable region 1000-1, wherein the stretchable region 1000-2 may be a region not covered with (e.g., exposed from, in the Z direction) the non-stretchable pattern 110b on the stretchable substrate 110a, and the non-stretchable region 1000-1 may be a region covered with (e.g., overlapped by, in the Z direction) the non-stretchable pattern 110b. The non-stretchable pattern 110b may include a plurality of planar patterns 110b-1 and a plurality of bridge patterns 110b-2, wherein on the plurality of planar patterns 110b-1, a plurality of unit elements 130 defining a plurality of pixels PX are disposed. The stretchable substrate 110a, the non-stretchable pattern 110b, the planar patterns 110b-1, the bridge patterns 110b-2, the unit elements 130 and the strain sensor 300 are the same as described above, for example with regard to the example embodiments as shown in FIGS. 6-7.

However, the stretchable panel 1000 according to some example embodiments, including the example embodiments shown in FIGS. 12-13, unlike the stretchable panel 1000 according to some example embodiments, including the example embodiments shown in FIGS. 6-7, includes a pixel circuit 120 electrically connected to each unit element 130, wherein the pixel circuit 120 includes a first pixel circuit 120a and a second pixel circuit 120b separated each other and further includes a connection electrode 140 connecting the first pixel circuit 120a and the second pixel circuit 120b. At least a portion of the first pixel circuit 120a or the second pixel circuit 120b may be in the stretchable region 1000-2.

The pixel circuit 120 may be repeatedly arranged on the stretchable substrate 110a (e.g., on upper surface 110as) and may be disposed around each pixel PX to independently control and/or drive each pixel PX. The pixel circuit 120 may include elements configured to independently control and/or drive each pixel (or subpixel), and may include, for example, a plurality of thin film transistors (TFTs) and capacitors. The plurality of thin film transistors (TFT) may include at least one switching thin film transistor (switching TFT) and at least one driving thin film transistor (driving TFT).

Each pixel circuit 120 may be disposed in the center of one pixel PX and includes a first pixel circuit 120a and a second pixel circuit 120b that are separated from each other (e.g., isolated from direct contact with each other) but are electrically connected to each other. At least a portion of the first pixel circuit 120a or the second pixel circuit 120b may be in the stretchable region 1000-2.

For example, the first pixel circuit 120a may be in the non-stretchable region 1000-1 that is formed on the non-stretchable pattern 110b and the second pixel circuit 120b may be formed on the stretchable substrate 110a on which the non-stretchable pattern 110b is not formed and may be disposed in the stretchable region 1000-2. For example, the first pixel circuit 120a may include a non-stretchable thin film transistor (non-stretchable TFT) and a capacitor, and the second pixel circuit 120b may include a stretchable thin film transistor (stretchable TFT).

For example, one of the first pixel circuit 120a or the second pixel circuit 120b may be a driving thin film transistor, and the other of the first pixel circuit 120a or the second pixel circuit 120b may be a switching thin film transistor.

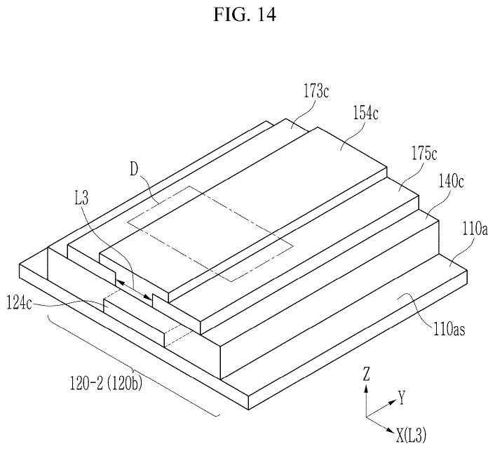

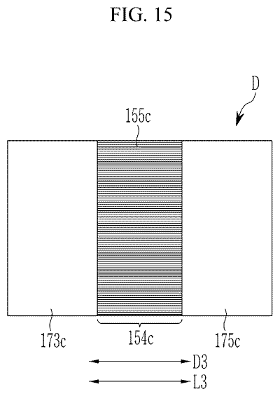

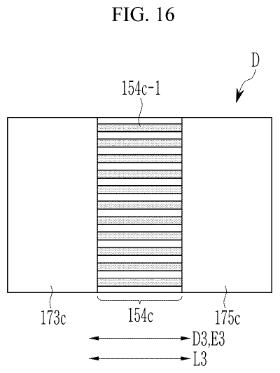

FIG. 14 is a perspective view schematically showing a pixel circuit (e.g., second pixel circuit) of the stretchable panel illustrated in FIGS. 12 and 13 according to some example embodiments, and FIGS. 15 and 16 are schematic views showing portion D of the second pixel circuit of FIG. 14 according to some example embodiments.

For example, the first pixel circuit 120a may be a driving thin film transistor and may include a second gate electrode 124b, a second gate insulating layer 140b, a second source electrode 173b, a second drain electrode 175b, and a second polymer semiconductor layer 154b, as illustrated in FIGS. 9 to 11. The second polymer semiconductor layer 154b may include a polymer (polymer chain) 155b oriented in one direction, and the orientation direction D2 of the polymer chain 155b may be substantially parallel to the second channel length direction L2 from the second source electrode 173b to the second drain electrode 175b.

For example, referring to FIG. 14, the second pixel circuit 120b may be a switching thin film transistor and may include a third gate electrode 124c, a third gate insulating layer 140c, a third source electrode 173c, a third drain electrode 175c, and a third polymer semiconductor layer 154c, as illustrated in FIGS. 14 to 16.

The third gate electrode 124c may be made of (e.g., at least partially comprise) a metal such as gold (Au), copper (Cu), nickel (Ni), aluminum (AI), molybdenum (Mo), chromium (Cr), tantalum (Ta), titanium (Ti), or any alloy thereof; a conductive nanostructure such as a nanowire or a nanotube; or any combination thereof, but is not limited thereto. For example, the third gate electrode 124c may be a stretchable electrode and may include, for example, a conductive layer having a plurality of microcracks.

The third gate insulating layer 140c may be formed on the whole surface of the stretchable substrate 110a and may be disposed between the third gate electrode 124c and the third polymer semiconductor layer 154c. The third gate insulating layer 140c may be made of an organic insulator, an inorganic insulator, and/or an organic-inorganic insulator, and may include, for example, a stretchable insulator. The third gate insulating layer 140c may have, for example, one layer or two or more layers. For example, the third gate insulating layer 140c may be made of (e.g., may at least partially comprise) an elastic polymer including, for example, polydimethylsiloxane (PDMS), thermoplastic polyurethane (TPU), styrene-ethylene-butylene-styrene (SEBS), styrene-ethylene-propylene-styrene (SEPS), styrene-butadiene-styrene (SBS), styrene-isoprene-styrene (SIS), styrene-isobutylene-styrene (SIBS), or any combination thereof, but is not limited thereto.

The third source electrode 173c and the third drain electrode 175c may face each other with the third polymer semiconductor layer 154c interposed therebetween, and may be electrically connected to the third polymer semiconductor layer 154c. The third source electrode 173c and the third drain electrode 175c may be made of (e.g., at least partially comprise) a metal such as gold (Au), copper (Cu), nickel (Ni), aluminum (AI), molybdenum (Mo), chromium (Cr), tantalum (Ta), titanium (Ti), or any alloy thereof; a conductive nanostructure such as a nanowire or a nanotube; or any combination thereof, but is not limited thereto. For example, the third source electrode 173c and the third drain electrode 175c may each independently be a stretchable electrode and may include, for example, a conductive layer having a plurality of microcracks.

The third polymer semiconductor layer 154c is overlapped with the third gate electrode 124c along the thickness direction (e.g., Z direction extending perpendicular to the upper surface 110as) of the stretchable substrate 110a. The third polymer semiconductor layer 154c may include a polymer (polymer chain) 155c oriented in one direction, and the orientation direction D3 of the polymer chain 155c may be parallel or substantially parallel to the third channel length direction L3 extending from the third source electrode 173c to the third drain electrode 175c. Here, the third channel length direction L3 may be a direction in which charge carriers (e.g., electrons) move from the third source electrode 173c to the third drain electrode 175c when voltage is applied to the third gate electrode 124c. As shown in at least FIG. 14, in some example embodiments the third source electrode 173c and the third drain electrode 175c may at least partially overlap each other in a horizontal direction extending in parallel with the stretchable substrate 110a (e.g., in parallel with the upper surface 110as thereof), for example the X direction as shown in FIG. 14, such that the third channel length direction L3 may be a direction extending in parallel with the stretchable substrate 110a (e.g., in parallel with the upper surface 110as thereof), for example extending in the X direction. However, it will be understood that relative arrangements of the third source electrode 173c and the third drain electrode 175c in relation to the stretchable substrate 110a, and thus the direction in which the third channel length direction L3 extends in relation to the stretchable substrate 110a, are not limited thereto.

In this way, since the polymer chains 155c of the third polymer semiconductor layer 154c are oriented parallel or substantially parallel to the third channel length direction L3, when voltage is applied to the third gate electrode 124c, the charges (electrons) of the second pixel circuit 120b may more effectively move along the polymer chains 155c, thereby exhibiting higher charge mobility. In addition, even if strain occurs in the third channel length direction L3, it does not significantly affect the arrangement of the polymer chains 155c, and thus more stable charge transfer characteristics may be exhibited. As a result, the stretchable panel 1000 may have improved functionality by virtue of the pixel circuit(s) 120 (e.g., second pixel circuit 120b) of the stretchable panel 1000 being configured to exhibit more stable charge transfer characteristics and/or higher charge mobility to reduce, minimize, or prevent degradation of display performance by the stretchable panel 1000 due to local strain in the stretchable panel 1000.

For example, referring to FIG. 16, the third polymer semiconductor layer 154c may include a plurality of semiconductor stripes 154c-1 extending in parallel along one direction (e.g., E3), and each semiconductor stripe 154c-1 may include at least a portion of the aforementioned polymer chains 155c. The extending direction E3 of the plurality of semiconductor stripes 154c-1 may be parallel or substantially parallel to the third channel length direction L3, which may be the same or substantially the same as the orientation direction D3 of the polymer chains 155c.

For example, the third polymer semiconductor layer 154c may further include a two-dimensional semiconducting material in addition to the polymer (polymer chains) 155c. The two-dimensional semiconducting material may include at least one metal element such as Mo, W, Nb, Ta, Pt, Pd, Co, Cr, Cu or Ni and at least one of chalcogen element such as S, Se or Te. For example, the two-dimensional semiconducting material may include MoS₂, MoSe₂, MoSSe, MoSTe, Mo₍₁₋ₓ₎WₓS₂, Mo₍₁₋ₓ₎WₓSe₂, Mo₍₁₋ₓ₎WₓTe₂, Mo₍₁₋ₓ₎NbₓS₂, Mo₍₁₋ₓ₎NbₓSe₂, Mo₍₁₋ₓ₎TaₓS₂, Mo₍₁₋ₓ₎TaₓSe₂, Mo₍₁₋ₓ₎WₓSSe, MoTe₂, WS₂, WSe₂, WSSe, WTe₂, WSTe, W₍₁₋ₓ₎NbₓS₂, W₍₁₋ₓ₎NbₓSe₂, PtS₂, PtSe₂, PtTe₂, PdSe₂, TaS₂, TaSe₂, Ta₍₁₋ₓ₎WₓS₂, Ta₍₁₋ₓ₎WₓSe₂ (herein, 0≤x≤1), and/or any combination thereof, but are not limited thereto.

For example, the third polymer semiconductor layer 154c may further include an elastomer. The elastomer may include, for example, polydimethylsiloxane (PDMS), styrene-ethylene-butylene-styrene (SEBS), styrene-ethylene-propylene-styrene (SEPS), styrene-butadiene-styrene (SBS), styrene-isoprene-styrene (SIS), styrene-isobutylene-styrene (SIBS), and/or any combination thereof, but are not limited thereto.

For example, the strain sensor 300 may be formed simultaneously with the first pixel circuit 120a and/or the second pixel circuit 120b through the same process. Accordingly, a stretchable panel 1000 including a strain sensor 300 may be manufactured without an additional process.

In the stretchable panel 1000 according to some example embodiments, a portion of the plurality of thin film transistors included in each pixel circuit 120 is disposed in a region (stretchable region) other than the pixel PX, so that an area occupied by the thin film transistors in the pixel PX may be reduced compared with a structure in which all the thin film transistors are disposed in each pixel PX, thereby overcoming a limitation of the reduction in a size of the pixel PX to effectively decrease the pixel size.

Specifically, the stretchable panel 1000 according to some example embodiments may secure a separate region (e.g., stretchable region 1000-2) for providing stretchability, and accordingly, an area occupied by the pixel PX relative to the total area of the stretchable substrate 110a may be inevitably reduced compared to a general panel (non-stretchable panel) using a glass substrate.

Meanwhile, in general, the size of the pixel PX may not be smaller than the area occupied by the pixel circuit 120. In some example embodiments, the area of the pixel circuit 120 in the pixel PX may be effectively reduced by overcoming this limitation and arranging a portion of the pixel circuit 120, i.e., a portion of the thin film transistor, in an area (stretchable area) other than the pixel PX, and accordingly, the size of the pixel PX may also be effectively reduced. Accordingly, the stretchable panel 1000 having a high resolution (e.g., higher pixel resolution) may be realized by overcoming the limitation of spatial arrangement of the stretchable panel 1000 and increasing the number of pixels PX per unit area on the stretchable substrate 110a.

In FIGS. 12 and 13, the first pixel circuit 120a, the second pixel circuit 120b, and the strain sensor 300 are illustrated in arbitrary shapes and sizes for convenience of explanation, but the first pixel circuit 120a, the second pixel circuit 120b, and the strain sensor 300 illustrated may vary in shape and size. Also, although the first pixel circuit 120a, the second pixel circuit 120b, and the strain sensor 300 are shown at arbitrary positions in FIGS. 12 and 13 for convenience of explanation, the first pixel circuit 120a may be anywhere in the non-stretchable region 1000-1 of the stretchable substrate 110a, and the second pixel circuit 120b and the strain sensor 300 may be anywhere in the stretchable region 1000-2 of the stretchable substrate 110a.

The connection electrode 140 may electrically connect the first pixel circuit 120a in the non-stretchable region 1000-1 and the second pixel circuit 120b in the stretchable region 1000-2. The connection electrode 140 may be disposed over the stretchable region 1000-2 and the non-stretchable region 1000-1. For example, one end of the connection electrode 140 may be disposed in the stretchable region 1000-2 and the other end of the connection electrode 140 may be disposed in the non-stretchable region 1000-1. The connection electrode 140 may be, for example, a stretchable electrode, and the stretchable electrode may include, for example, a conductive polymer, conductive metal particles, liquid metal, cracked metal such as cracked Au, or any combination thereof, but is not limited thereto.

As described above, in the stretchable panel 1000 according to some example embodiments, at least a portion of the pixel circuit 120 (e.g., at least a portion of a thin film transistor) may be disposed in the stretchable region 1000-2, so that a limitation of the pixel arrangement space due to the stretchable region 1000-2 may be overcome and the number of pixels per unit area may be increased. For example, the number of pixels per unit area in the stretchable panel 1000 may be greater than or equal to about 150 ppi (pixel per inch), greater than or equal to about 200 ppi, greater than or equal to about 250 ppi, greater than or equal to about 300 ppi, greater than or equal to about 350 ppi, greater than or equal to about 400 ppi, greater than or equal to about 450 ppi, or greater than or equal to about 500 ppi and may be, for example, about 150 ppi to about 1000 ppi, about 200 ppi to about 1000 ppi, about 250 ppi to about 1000 ppi, about 300 ppi to about 1000 ppi, about 350 ppi to about 1000 ppi, about 400 ppi to about 1000 ppi, about 450 ppi to about 1000 ppi, or about 500 ppi to about 1000 ppi.

Hereinafter, another example of a stretchable panel according to some example embodiments will be described.

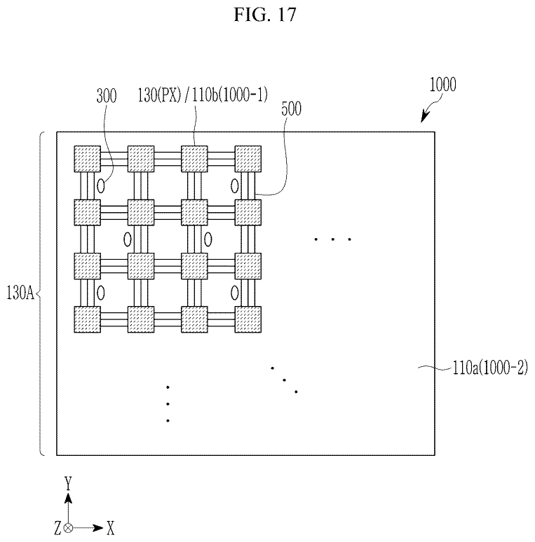

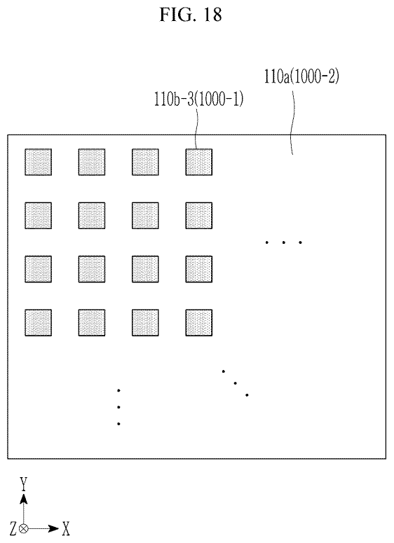

FIG. 17 is a plan view schematically showing an example of a stretchable panel according to some example embodiments, and FIG. 18 is a plan view showing an example of the arrangement of the non-stretchable pattern in the stretchable panel of FIG. 17.

Referring to FIGS. 17 and 18, the stretchable panel 1000 according to some example embodiments, like some example embodiments, including the example embodiments shown in FIGS. 6-7 and 12-13, includes the stretchable region 1000-2 and the non-stretchable region 1000-1, wherein the stretchable region 1000-2 may be a region not covered with the non-stretchable pattern 110b on a stretchable substrate 110a, and the non-stretchable region 1000-1 may be a region covered with the non-stretchable pattern 110b.

However, the stretchable panel 1000 according some example embodiments, including the example embodiments show in FIGS. 17-18, unlike the stretchable panel 1000 according to some example embodiments, including the example embodiments shown in FIGS. 6-7 and 12-13, includes a plurality of island-shaped patterns 110b-3 where the non-stretchable patterns 110b are separated one another on the stretchable substrate 110a. Each unit element 130 of an array 130A of unit elements is positioned on each (e.g., a separate) island-shaped pattern 110b-3 (the non-stretchable region 1000-1), and a wiring 500 and the strain sensors 300 are mainly positioned on the stretchable substrate 110a (the stretchable region 1000-2).

The wiring 500 may be mainly disposed in the stretchable region 1000-2 and electrically connect the neighboring unit elements 130 of the array 130A between neighboring island-shaped pattern 110b-3. For example, the wiring 500 may include a gate wire extending in a first direction (e.g., X direction) and a data wire and/or a driving voltage wire extending in a second direction (e.g., Y direction) but is not limited thereto. In the drawing, the wiring 500 is illustratively shown as a straight line extending in the first direction (e.g., X direction) and the second direction (e.g., Y direction), but is not limited thereto, and may have a stretchable shape such as a wave shape, a pop-up shape, or a non-planar mesh shape.

The aforementioned stretchable panel 1000 may be applied to various fields requiring flexibility and/or stretchability, and may be, for example, a stretchable display panel or a stretchable sensor array. The stretchable panel 1000 may be, for example, a bendable display panel, a foldable display panel, a rollable display panel, a wearable device, a skin-type stretchable display panel, a skin-like display panel, a skin-like sensor array, a large-area conformable display, smart clothing, or the like, but is not limited thereto.

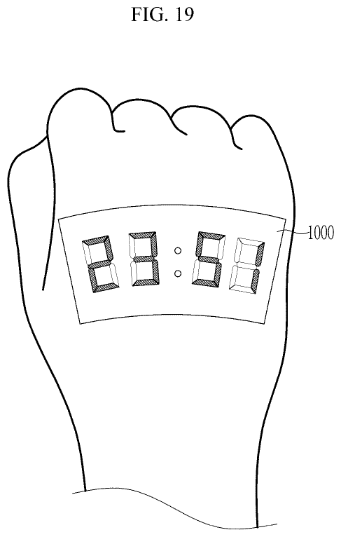

FIG. 19 is a schematic view showing a skin-type stretchable display panel according to some example embodiments.

Referring to FIG. 19, the aforementioned stretchable panel 1000 may be a skin-type display panel that is an ultrathin display panel, and may display particular (or, alternatively, predetermined) information such as various characters and/or images.

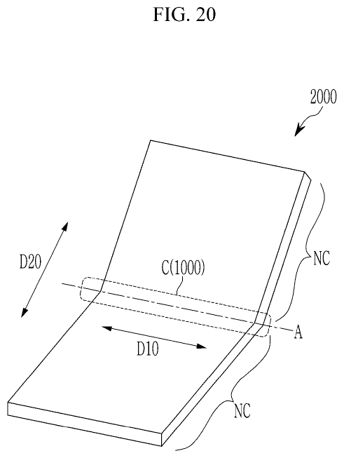

FIGS. 20, 21, 22, and 23 are schematic views each showing examples of a stretchable display panel according to examples.

The stretchable display panel 2000 according to some example embodiments may be a display panel configured to be flexibly deformed by a user or an external force by introducing a structurally deformable portion into a screen for displaying an image. Herein, the structurally deformable portion may be at least a portion inside the screen.

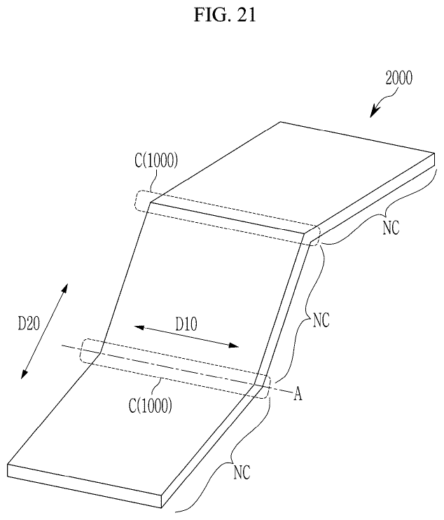

Referring to FIGS. 20 and 21, the stretchable display panel 2000 according to some example embodiments may be a foldable display panel of which a screen may be folded into one or more than one along a particular (or, alternatively, predetermined) direction. The foldable display panel shown in FIG. 20 is one-axis foldable display panel of which a screen may be folded along one axis (A), and the foldable display panel shown in FIG. 21 is a multi-axis foldable display panel of which a screen may be folded along two axes (A). However, the present inventive concepts are not limited thereto, but the number of axis (A) may be three or more. FIG. 20 illustrates an in-folding type in which the screen is folded inward, but the present inventive concepts are not limited thereto but may be similarly applied to an out-folding type in which the screen is folded outward.

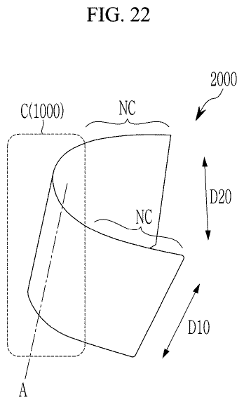

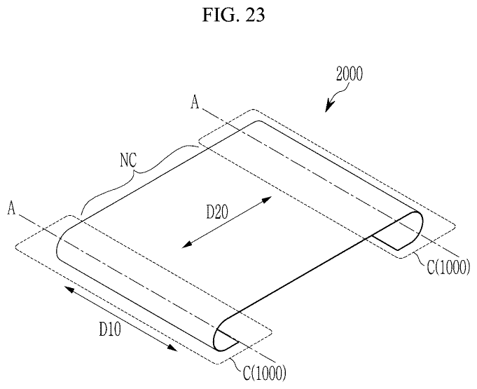

Referring to FIG. 22, the stretchable display panel 2000 according to some example embodiments may be a bendable display panel capable of bending a screen along a particular (or, alternatively, predetermined) direction. Referring to FIG. 23, the stretchable display panel 2000 according to some example embodiments may be a rollable display panel capable of rolling the screen along a particular (or, alternatively, predetermined) direction.

Referring to FIGS. 20 to 23, the stretchable display panel 2000 may be folded, bent, or rolled along at least one axis A extending in the first direction D10. The stretchable display panel 2000 may include a deformable section C folded, bent, or rolled along the axis A and a non-deformable section NC excluding the deformable section C.

The deformable section C may be a folding section, a bending section, or a rolling section which is deformed into a curve around the axis A, wherein one or more than one may be included in the stretchable display panel 2000. The deformable section C may be a region where a radius of curvature, which refers to a degree of being folded, bent, or rolled up to a maximum without substantial damage, is defined and where stress is concentrated, when repetitively folded, bent, or rolled. The stress may act on the deformable section C in a direction of being repetitively folded, bent, or rolled, for example, in a second direction D20 perpendicular or substantially perpendicular to the first direction D10. The non-deformable section NC may be a flat section or have relatively smaller stress than the deformable section C, but the present inventive concepts are not limited thereto.

The deformable section C of the stretchable display panel 2000 may include the stretchable panel 1000 including the non-stretchable region 1000-1 and the stretchable region 1000-2 shown in FIGS. 6 to 18.

The stretchable region 1000-2 is a region capable of flexibly responding to an external force such as twisting, pressing, and pulling and may include, as described above, an elastomer having a relatively low elastic modulus, and accordingly, may provide the deformable section C of the stretchable display panel 2000 with stretchability to reduce stress acting when repetitively folded, bent, or rolled, and thus prevent, minimize, or reduce damage in the deformable section C.

The non-stretchable region 1000-1 is a region that is not substantially deformed or very slightly deformed due to relatively high resistance to the external force such as twisting, pressing, and pulling and may include a particular material including an organic material, an inorganic material, an organic/inorganic material, or any combination thereof, where the particular material has a relatively high elastic modulus, as described above.

Unlike the deformable section C, the non-deformable section NC of the stretchable display panel 2000 may not include a separate stretchable region 1000-2 and may include the non-stretchable region 1000-1. Accordingly, the non-deformable section NC of the stretchable display panel 2000 may be covered with the non-stretchable pattern 110b on the stretchable substrate 110a, and the whole non-deformable section NC may be covered with, for example, a plate-shaped non-stretchable pattern 110b.

As described above, the stretchable display panel 2000 according to some example embodiments is manufactured, by disposing the stretchable region 1000-2 in the deformable section C such as a folding section, a bending section, or a rolling section to effectively reduce stress applied when repetitively folded, bent, or rolled, and thus prevent, minimize, or reduce damage in the deformable section C. In addition, this reduction of the stress applied in the deformable section C may realize a foldable, bendable, or rollable display panel with a small curvature, for example, less than or equal to about 1 mm, less than or equal to about 0.8 mm, less than or equal to about 0.5 mm, less than or equal to about 0.3 mm, less than or equal to about 0.2 mm, or less than or equal to about 0.1 mm, and/or greater than about 0.01 mm, greater than about 0.05 mm, greater than about 0.1 mm, or the like.

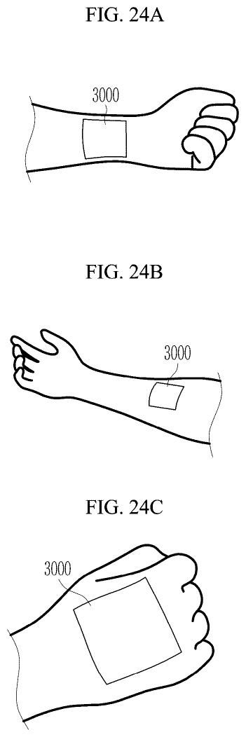

FIGS. 24A, 24B, and 24C are schematic views illustrating skin-type sensor arrays according to some example embodiments.

Referring to FIGS. 24A to 24C, the skin-type sensor array 3000 according to an example may be an attachable biometric sensor array, and may include the aforementioned stretchable panel 1000. The skin-type sensor array 3000 may be attached to a biological surface such as skin, a living body such as an organ, or an indirect means contacting a living body such as clothes to sense and measure biological information such as a biological signal. For example, the biosensor array includes an electroencephalogram (EEG) sensor, an electrocardiogram (ECG) sensor, a blood pressure (BP) sensor, an electromyography (EMG) sensor, a blood glucose (BG) sensor, a photoplethysmography (PPG) sensor, an accelerometer, a RFID antenna, an inertial sensor, an activity sensor, a strain sensor, a motion sensor, or any combination thereof, but is not limited thereto. The skin-type sensor array 3000 (e.g., biosensor array) may be attached to a living body in a very thin patch type or band type to monitor biometric information in real time. For example, the skin-type sensor array 3000 may be a sensor array including a photo blood flow measurement sensor (PPG sensor), and the biometric information may include heart rate, oxygen saturation, stress, arrhythmia, blood pressure, etc., and biometric information may be obtained by analyzing the waveform of an electrical signal.

The aforementioned stretchable panel 1000 and the stretchable display panel 2000 or the skin-type sensor array 3000 (e.g., biosensor array) including the stretchable panel 1000 may be included in various electronic devices, and the electronic device may further include a processor (not shown) and a memory (not shown).

The electronic devices may include, for example, mobile phones, video phones, smart phones, smart pads, smart watches, digital cameras, tablet PCs, laptop PCs, notebook computers, computer monitors, wearable computers, televisions, digital broadcasting terminals, e-books, and personal digital assistants (PDAs), PMP (portable multimedia player), EDA (enterprise digital assistant), head mounted displays (HMD), in-vehicle navigations, Internet of Things (IoT), Internet of Everything (IoE), security devices, medical devices, but are not limited thereto.

Hereinafter, some example embodiments are illustrated in more detail with reference to examples. However, the present scope of the inventive concepts is not limited to these examples.

### Manufacturing of Stretchable Device

### Example 1

Au is thermally deposited on a styrene-ethylene-butylene-styrene (SEBS) substrate to form a gate electrode, and then a SEBS solution (Tuftec H1052, Asahi Kasei) is applied thereon and then, annealing it at 100° C. for 0.5 hours to form a gate insulator. Subsequently, the gate insulator is patterned by a photolithography process to form a plurality of trenches extending in one direction (first direction) with intervals of about 5 μm, each of the trenches having a width of about 10 μm and a depth of about 30 μm. Subsequently, a polymer solution of the polymers represented by Chemical Formula A (a weight average molecular weight: 210,000) and SEBS (an elastomer) in a weight ratio of 3:7 at a concentration of 0.6 wt % in chlorobenzene is passed through the plurality of trenches and then, heat-treating it at 100° C. for 1 hour under a nitrogen atmosphere (polymer orientation process) to form a polymer semiconductor layer, in which polymers are oriented parallel to the first direction. Subsequently, on the polymer semiconductor layer, Au is thermally deposited to form a source electrode and a drain electrode in a channel length direction (a source electrode-drain electrode direction), which is set to be a second direction perpendicular to the first direction, manufacturing a thin film transistor. The thin film transistor has a width/length ratio of 25/10.

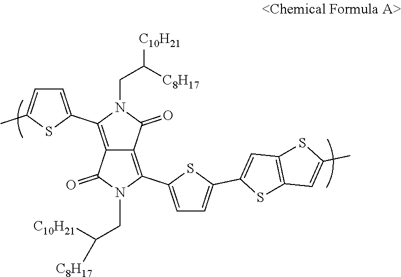

### Reference Example 1

A thin film transistor is manufactured in the same manner as in Example 1 except that the polymer orientation process is not performed.

### Reference Example 2

A thin film transistor is manufactured in the same manner as in Example 1 except that the channel length direction (source electrode-drain electrode direction) of the thin film transistor is set to be the same direction (first direction) as the polymer orientation direction of the polymer semiconductor layer.

### Evaluation I

The thin film transistors according to Example 1 and Reference Example 1 are evaluated with respect to orientation degrees of the polymer semiconductor layers.

The orientation degrees of the polymer semiconductor layers are quantified by using two-dimensional fast Fourier transform (2D-FFT) after analyzing the thin film surface through atomic force microscopy (AFM).

The results are shown in Table 1.

TABLE 1

| | 2D FFT <cos²θ> |
|---|---|
| Example | 0.6 |
| Reference Example 1 | 0.51 |

Referring to Table 1, the polymer semiconductor layer of the thin film transistor according to Reference Example 1 has isotropic, which is not oriented in a particular (or, alternatively, predetermined) direction, but the polymer semiconductor layer of the thin film transistor according to Example 1 has the orientation in one direction.

### Evaluation II

The thin film transistors according to Example 1 and Reference Example 2 are evaluated with respect to electrical characteristics, while respectively stretching in a parallel direction (P) to the source electrode-drain electrode direction (a channel length direction) and in a vertical direction (V) to the source electrode-drain electrode direction at a stretching rate (0 to 25%). Herein, the stretching rate refers to a length change rate relative to an initial length, and the stretching direction is a strain direction.

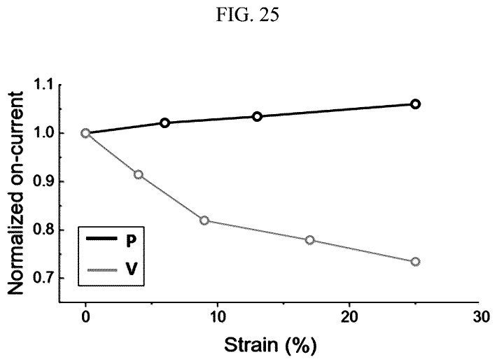

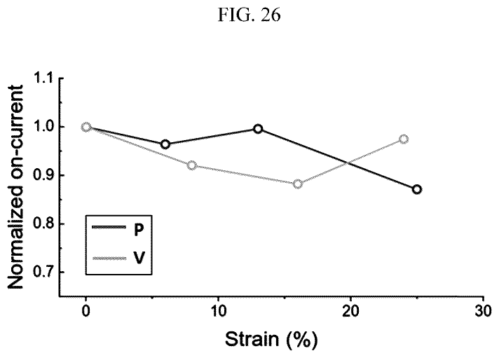

FIG. 25 is a graph showing the change in current characteristics according to the stretching rate when the thin film transistor according to Example 1 is stretched in the direction parallel to the source electrode-drain electrode direction (channel length direction) and in the direction perpendicular to the source electrode-drain electrode direction (channel length direction), and FIG. 26 is a graph showing the change in current characteristics according to the stretching rate when the thin film transistor according to Reference Example 2 is stretched in the direction parallel to the source electrode-drain electrode direction (channel length direction) and in the direction perpendicular to the source electrode-drain electrode direction (channel length direction).

Referring to FIG. 25, the thin film transistor according to Example 1 has a larger electrical characteristic difference according to the stretching direction, as the stretching rate increases. Accordingly, it may be confirmed that the thin film transistor according to Example 1 acts as a strain sensor configured to detect the stretching direction and a stretching size.

On the contrary, referring to FIG. 26, the thin film transistor according to Reference Example 2 exhibits neither larger difference nor tendency in the electrical characteristics according to the stretching rate and the stretching direction, and accordingly, it may be confirmed that the thin film transistor according to Reference Example 2 is difficult to apply as a strain sensor configured to detect stain.

While the inventive concepts have been described in connection with what is presently considered to be practical example embodiments, it is to be understood that the inventive concepts are not limited to such example embodiments. On the contrary, is the inventive concepts are intended to cover various modifications and equivalent arrangements included within the spirit and scope of the appended claims.

What is claimed is:

1. A stretchable panel, comprising:
a stretchable substrate; and
a strain sensor on the stretchable substrate,
wherein the strain sensor includes
a first gate electrode,
a first polymer semiconductor layer overlapped with the first gate electrode along a thickness direction of the stretchable substrate, the first polymer semiconductor layer including polymer chains of the first polymer semiconductor layer, and
a first source electrode and a first drain electrode electrically connected to the first polymer semiconductor layer and facing each other with the first polymer semiconductor layer interposed therebetween, and
wherein the polymer chains of the first polymer semiconductor layer are oriented so as to cross a first channel length direction extending from the first source electrode to the first drain electrode.

2. The stretchable panel of claim 1, wherein the polymer chains of the first polymer semiconductor layer are oriented at an angle of 45 degrees to 135 degrees with respect to the first channel length direction.

3. The stretchable panel of claim 1, wherein the polymer chains of the first polymer semiconductor layer are oriented perpendicularly to the first channel length direction.

4. The stretchable panel of claim 1, wherein
the first polymer semiconductor layer comprises a plurality of semiconductor stripes extending perpendicularly to the first channel length direction, and
each semiconductor stripe of the plurality of semiconductor stripes comprises at least a portion of the polymer chains of the first polymer semiconductor layer.

5. The stretchable panel of claim 1, further comprising a non-stretchable pattern on the stretchable substrate and having a higher elastic modulus than the stretchable substrate,
wherein the stretchable panel comprises
a non-stretchable region in which the stretchable substrate and the non-stretchable pattern are arranged to be overlapped each other, and
a stretchable region excluding the non-stretchable region, and
wherein the strain sensor is in the stretchable region.

6. The stretchable panel of claim 5, wherein
the strain sensor comprises first and second strain sensors which are arranged separately from each other in the stretchable region, and
the first channel length direction of the second strain sensor is different from the first channel length direction of the first strain sensor.

7. The stretchable panel of claim 5, further comprising a plurality of unit elements and a plurality of pixel circuits electrically connected to the plurality of unit elements,
wherein the plurality of unit elements comprise a light emitting diode, a photoelectric conversion diode, or any combination thereof, and
the plurality of unit elements are in the non-stretchable region.

8. The stretchable panel of claim 7, wherein at least a portion of at least one pixel circuit of the plurality of pixel circuits is in the non-stretchable region.

9. The stretchable panel of claim 7, wherein a portion of at least one pixel circuit of the plurality of pixel circuits is in the non-stretchable region and a separate portion of the at least one pixel circuit is in the stretchable region.

10. The stretchable panel of claim 7, wherein
at least one pixel circuit of the plurality of pixel circuits comprises a thin film transistor,
the thin film transistor comprises
a second gate electrode,
a second polymer semiconductor layer overlapped with the second gate electrode along the thickness direction of the stretchable substrate, the second polymer semiconductor layer including polymer chains of the second polymer semiconductor layer, and
a second source electrode and a second drain electrode electrically connected to the second polymer semiconductor layer and facing each other with the second polymer semiconductor layer interposed therebetween, and
the polymer chains of the second polymer semiconductor layer are oriented parallel to a second channel length direction extending from the second source electrode to the second drain electrode.

11. The stretchable panel of claim 10, wherein the first polymer semiconductor layer and the second polymer semiconductor layer comprise a same polymer.

12. A stretchable panel, comprising:
a stretchable substrate; and
a first thin film transistor and a second thin film transistor are arranged on the stretchable substrate,
wherein the first thin film transistor includes
a first gate electrode,
a first polymer semiconductor layer overlapped with the first gate electrode along a thickness direction of the stretchable substrate, the first polymer semiconductor layer including polymer chains of the first polymer semiconductor layer, and
a first source electrode and a first drain electrode electrically connected to the first polymer semiconductor layer and facing each other with the first polymer semiconductor layer interposed therebetween,
wherein the second thin film transistor includes
a second gate electrode,
a second polymer semiconductor layer overlapped with the second gate electrode along the thickness direction of the stretchable substrate, the second polymer semiconductor layer including polymer chains of the second polymer semiconductor layer, and
a second source electrode and a second drain electrode electrically connected to the second polymer semiconductor layer and facing each other with the second polymer semiconductor layer interposed therebetween,
wherein the polymer chains of the first polymer semiconductor layer are oriented so as to cross a first channel length direction extending from the first source electrode to the first drain electrode, and
wherein the polymer chains of the second polymer semiconductor layer are oriented parallel to a second channel length direction extending from the second source electrode to the second drain electrode.

13. The stretchable panel of claim 12, wherein the polymer chains of the first polymer semiconductor layer are oriented at an angle of 45 degrees to 135 degrees with respect to the first channel length direction.

14. The stretchable panel of claim 12, wherein the polymer chains of the first polymer semiconductor layer are oriented perpendicularly to the first channel length direction.

15. The stretchable panel of claim 12, further comprising a non-stretchable pattern on the stretchable substrate and having a higher elastic modulus than the stretchable substrate,
wherein the stretchable panel comprises
a non-stretchable region in which the stretchable substrate and the non-stretchable pattern are arranged to be overlapped each other, and a stretchable region excluding the non-stretchable region,
wherein the first thin film transistor is in the stretchable region, and wherein the second thin film transistor is in the non-stretchable region.

16. The stretchable panel of claim 15, further comprising a third thin film transistor electrically connected to the second thin film transistor,
wherein the third thin film transistor comprises
a third gate electrode,
a third polymer semiconductor layer overlapped with the third gate electrode along the thickness direction of the stretchable substrate, the third polymer semiconductor layer including polymer chains of the third polymer semiconductor layer, and
a third source electrode and a third drain electrode electrically connected to the third polymer semiconductor layer and facing each other with the third polymer semiconductor layer interposed therebetween,
wherein the polymer chains of the third polymer semiconductor layer are oriented parallel to a third channel length direction extending from the third source electrode to the third drain electrode, and
wherein the third thin film transistor is in the stretchable region.

17. The stretchable panel of claim 16, wherein the first polymer semiconductor layer and the third polymer semiconductor layer comprise a same polymer.

18. The stretchable panel of claim 17, wherein
the first polymer semiconductor layer comprises a plurality of semiconductor stripes extending perpendicularly to the first channel length direction and comprising the polymer, and
the third polymer semiconductor layer comprises a separate plurality of semiconductor stripes extending parallel to the third channel length direction and comprising the polymer.

19. The stretchable panel of claim 15, further comprising a unit element electrically connected to the second thin film transistor,
wherein the unit element comprises a light emitting diode, a photoelectric conversion diode, or any combination thereof, and
the unit element is in the non-stretchable region.

20. An electronic device comprising the stretchable panel of claim 1.
